(19) United States
(12) Patent Application Publication
(10) Pub. No.: US 2005/0045092 A1
(43) Pub. Date: Mar. 3, 2005

(54) Method of multi-element compound deposition by atomic layer deposition for IC barrier layer applications

(75) Inventors: Chii-Ming Wu, Taipei (TW); Chao-Hsien Peng, Hsinchu City (TW); Shau-Lin Shue, Hsinchu (TW)

Correspondence Address: GEORGE O. SAILE, 28 DAVIS AVENUE, POUGHKEEPSIE, NY, 12603, US

(73) Assignee: Taiwan Semiconductor Manufacturing Co.

(21) Appl. No.: 10/653,852

(22) Filed: Sep. 3, 2003

(51) Int. Cl. C30B 23/00; C30B 25/00; C30B 28/12; C30B 28/14

(52) U.S. Cl. 117/92; 117/103

(57) ABSTRACT

An ALD method is described for depositing a composite layer comprised of three to five elements including one or two metals, Si, B and N. A metal containing gas is injected into a process chamber and purged followed by a N source gas and a purge and/or a Si or B source gas and a purge to complete a cycle and form a monolayer. A predetermined number of monolayers each having two or three elements is deposited to provide a composite film with good step coverage and a well controlled composition. The resulting layer is especially useful as a diffusion barrier layer for copper. Alternatively, a three component layer comprised of Hf, Zr, and O may be deposited and serves as a gate dielectric layer in a MOSFET device. The invention is also a thin film comprised of a plurality of monolayers each having two or three elements.

### RELATED PATENT APPLICATION

This application is related to the following: Docket # TSMC01-1247, Ser. No. ______, filing date ______, assigned to a common assignee.

### FIELD OF THE INVENTION

The invention relates to the field of fabricating integrated circuits and in particular to an atomic layer deposition (ALD) method of forming a multi-element film that is used as a diffusion barrier layer or as a gate dielectric layer during the fabrication of a semiconductor device.

### BACKGROUND OF THE INVENTION

As the gate length of polysilicon gates in transistor devices and the width of wiring in metal interconnects continues to shrink in semiconductor manufacturing, the thickness of layers used to protect and insulate these conductive features is also decreasing. For example, metal interconnects for new technologies that have a critical dimension (CD) approaching 100 nm are fabricated with copper and are protected by a thin diffusion barrier layer that is conformally deposited in a trench and/or via prior to Cu deposition. When the trench or via opening becomes smaller and a thinner diffusion barrier layer is required, a conventional chemical vapor deposition (CVD) method of forming a uniform diffusion barrier layer becomes very difficult. It is likely that the top portion of an opening will have a thicker barrier layer than the bottom portion. This nonuniformity can lead to poor coverage of certain parts of a via opening such as bottom corners, for example. As a result, when copper is deposited, small voids can form between the metal layer and via sidewall that will detract from device performance. In other cases, insufficient barrier layer coverage in certain regions of a via or trench will not protect Cu from moisture or traces of other corrosive agents in the adjacent dielectric layers.

In metal-on-silicon field effect transistor (MOSFET) technology, a gate electrode is formed on a thin gate dielectric layer that is typically an oxide. The thickness of the gate oxide is critical to the performance of the device. There is a constant need for thinner oxides to allow a higher speed device with lower power consumption. For ultra thin SiO₂ gates, leakage current will increase tremendously as thickness is reduced. This will cause a large current in the standby mode (I_{OFF}) and a large standby power consumption, thereby making products with these devices commercially unacceptable. Therefore, higher k materials such as ZrO₂ and HfO₂ are being implemented in order to achieve lower effective oxide thickness without compromising the ability to prevent dopant migration between the gate and channel region. A gate dielectric layer consisting of a high k dielectric film with a thickness of less than 20 Angstroms is difficult to control by a CVD technique which usually has a relatively fast deposition rate.

ALD is a newer approach to forming thin films that has a more controllable deposition rate since only one monolayer is formed with each injection of reactant into a reaction chamber. ALD involves injecting a first reactant into a chamber and a monolayer of the reactant is absorbed on a substrate after the excess material is purged by an inert gas. A second reactant is injected into the chamber and reacts with the first monolayer. A monolayer of the second reactant may or may not be formed before the reaction with the first reactant. After excess second reactant is purged, the cycle may be repeated until the required thickness of the product film is obtained. Usually, each reaction between the first and second reactant builds a layer that is about 1 to 2 Angstroms thick. Therefore, many cycles may be needed to reach an appropriate thickness for a diffusion barrier layer. The substrate is normally heated to promote the reaction so that injection times are kept below 10 seconds and preferably close to 1 second or less.

Another benefit of ALD is that layer with three or more elements may be formed with a composition that can be varied according to the desired properties. The composition is finely tuned by controlling the order of injection of each reactant and the length of an injection. Optionally, some reactants may pass through a radical generator to increase the rate of reaction with the monolayer on the substrate surface.

In one prior art method described in U.S. Pat. No. 6,203,613, Ti(NO₃)₄ reacts with NH₃ to yield a 5 nm thick film of TiN after 167 cycles. Metal nitrates are used as reactants instead of metal chlorides in order to avoid a chloride contamination issue but nitrates are dangerous due to their explosive nature.

A slightly modified ALD technique is described in U.S. Pat. No. 6,270,572 in which a precursor is injected twice to enable a more complete coverage of a substrate before a reactant is introduced into the ALD chamber. The reactant is purged and reinjected to provide a precise stoichiometric composition. In this case a TiN film is grown at a rate of about 1 Angstrom per cycle using TiCl₄ as precursor and NH₃ as reactant.

A binary or ternary layer is formed by an ALD method in U.S. Pat. No. 6,468,924. Here, a first reactant containing a halogen is absorbed on a substrate. A H₂ treatment then removes the halogen from the monolayer. A second reactant such as NH₃ introduces N into the film. A third element is included by replacing the first halogen containing reactant with a second halogen containing reactant in some of the cycles. The H₂ treatment is likely to lengthen cycle time and reduce throughput.

A sequential CVD process in U.S. Pat. No. 5,916,365 is employed in depositing a ternary layer such as TiSiN by forming a monolayer of titanium silicide and then adding nitrogen radicals at a temperature of up to 500° C.

In U.S. Pat. No. 6,287,965, an ALD method is used to form an A-B-N composition where A is a reactive metal, B is an amorphous combination element, and N is nitrogen. The resulting film is a barrier layer, a lower electrode, or an upper electrode in a semiconductor device.

As an increasing number of requirements and tighter specifications are placed on barrier layers and gate dielectric layers, the conventional ALD method must be modified to satisfy particular needs in the industry. Besides retaining good barrier capability at shrinking thicknesses, barrier layers and gate dielectric layers should also be highly uniform with a controlled thickness and composition. Furthermore, it is desirable to fabricate a barrier layer with a flexible composition that can be fine tuned to adjust properties such as resistivity and adhesion.

### SUMMARY OF THE INVENTION

An objective of the present invention is to provide an ALD method that incorporates three or more reactants to form a composite layer with three or more elements.

A further objective of the present invention is to provide an ALD method for fabricating a gate dielectric layer with improved performance in a MOSFET transistor.

A still further objective of the present invention is to provide an ALD method of forming a diffusion barrier layer with good Cu barrier capability, uniform step coverage, and a well controlled composition that can be easily adjusted.

Yet another objective of the present invention is to provide an ALD structure that contains three or more elements that can be used as a diffusion barrier layer or a gate dielectric layer in a semiconductor device.

These objectives are achieved in a first embodiment by loading a substrate in a reaction chamber that is equipped with inlet ports for three or more gases and with an exit port. The substrate is heated and then a first reactant that is preferably a metal (M₁) containing compound is injected into the reaction chamber. After a short interval, an inert gas purges the first reactant from the chamber and leaves a monolayer of the first reactant on the substrate. A second reactant which is a nitrogen containing compound is injected into the chamber and may or may not form a second monolayer on the substrate before reacting with the first monolayer to form a metal nitride layer. After an inert gas or vacuum purges the second reactant, a third reactant which is a silicon containing or boron containing compound is injected into the chamber and may or may not form a monolayer on the substrate before reacting with the metal nitride layer to form a M₁SN monolayer where S is B or Si. Excess third reactant is removed from the chamber to complete a first cycle. The cycle which may involve one of three flows is repeated a plurality of times until an appropriate thickness of the composite layer is reached. The composite layer has the formula M_{1V}S_{X}N_{Z} where V, X, and Z are fractions between 0 and 1 and when added together equal 1. In one example, the composite layer forms a diffusion barrier layer in a copper interconnect scheme.

In a second embodiment, a composite layer comprised of two metals and oxygen is formed on a substrate by first forming a monolayer of a metal (M₁) containing compound in which M₁ is preferably hafnium (Hf) by injecting a first reactant into a reaction chamber and purging the chamber after a short interval. An oxygen containing source gas such as O₂ or H₂O₂ is injected and reacts with the metal containing monolayer to form a first metal oxide monolayer. The oxygen source is purged to complete a cycle. A second metal (M₂) containing compound that preferably comprises zirconium (Zr) is injected for a short interval and is then purged from the chamber to form a monolayer on the first metal oxide. An oxygen containing source gas is injected and purged after a short interval to complete a cycle. As a result, a monolayer of the second metal oxide is formed on a monolayer of the first metal oxide. The cycle to form a first metal oxide and the cycle to form a second metal oxide are each performed a plurality of times in an alternating fashion or in a random manner to deposit a composite layer with the formula M_{1P}M_{2Q}O_{R} where P, Q, and R are fractions between 0 and 1 and that together equal 1. The ternary layer is especially useful as a gate dielectric layer in a MOSFET structure.

In a third embodiment, a composite layer with four elements is formed by an ALD sequence that involves two different cycles. The composite layer has the formula M₁ᵥM_{2W}S_{X}N_{Z} where V, W, X and Z are fractions between 0 and 1 which when added together equal 1 and where S is Si or B. M₁ and M₂ are preferably Ti, Ta, or W but M₁ is different than M₂. In one aspect, a M₁SiN monolayer is formed in one cycle and a M₂SiN monolayer is formed in a second cycle. Alternatively, a M₁BN monolayer is formed in one cycle and a M₂BN monolayer is formed in a second cycle. Within each cycle, there are three possible flows. One flow forms a monolayer with three elements. A second flow forms a metal nitride monolayer and a third flow forms a M₁Si, M₂Si, M₁B, or M₂B monolayer. The two cycles are each performed a plurality of times and may be exercised in any order until a composite layer with an acceptable thickness and composition are achieved. The ALD sequence is ended after depositing a predetermined number of monolayers having a known thickness or by measuring the composite layer and verifying that the thickness is in a specified range.

In a fourth embodiment, a composite layer with four elements is formed by an ALD sequence that involves two different cycles. The composite layer has the formula M₁ᵥSi_{X}B_{Y}N_{Z} where V, X, Y and Z are fractions between 0 and 1 which when added together equal 1. M₁ is preferably Ti, Ta, or W. In one aspect, a M₁SiN monolayer is formed in one cycle and a M₁BN monolayer is formed in a second cycle. Within each cycle, there are three possible flows. One flow forms a monolayer with three elements. A second flow forms a metal nitride monolayer and a third flow forms a M₁Si or M₁B monolayer. The two cycles are each performed a plurality of times and may be exercised in any order until a composite layer with an acceptable thickness and composition are achieved. The ALD sequence is ended after depositing a predetermined number of monolayers having a known thickness or by measuring the composite layer and verifying that the thickness is in a specified range.

In a fifth embodiment, a composite layer comprised of five elements is formed by an ALD sequence that involves between two and four different cycles. The composite layer has the formula M₁ᵥM_{2W}Si_{X}B_{Y}N_{Z} where V, W, X, Y and Z are fractions between 0 and 1 which when added together equal 1. M₁ is different than M₂ and M₁ and M₂ are Ti, Ta, or W. In one aspect, a M₁ SiN monolayer is formed in one cycle and a M₂BN monolayer is formed in second cycle. Optionally, a M₁BN monolayer is formed in a third cycle and a M₂SiN monolayer is formed in a fourth cycle. Within each cycle, there are three possible flows. One flow forms a monolayer with three elements. A second flow forms a metal nitride monolayer and a third flow forms a M₁S or M₂S monolayer where S is Si or B. Two or more different cycles are each performed a plurality of times that may be executed in any order until a composite layer with an acceptable thickness and composition are achieved. The predetermined order is inputted into a software program in a computer that is linked to the ALD process chamber.

The present invention is also a thin film comprised of a plurality of monolayers. In one aspect, the thin film is a composite layer comprised three elements having a formula M_{1V}S_{X}N_{Z} layer in which M₁ is a metal, S is Si or B, and N is nitrogen and where V, X, and Z are fractions between 0 and 1 that when added together equal 1. In one example, the composite layer is comprised of M₁SiN, M₁N, and M₁Si monolayers. Optionally, the composite layer is comprised of M₁BN, M₁N, and M₁B monolayers. In either case, the composite layer is especially useful as a diffusion barrier layer in a metal interconnect structure, for example.

In another aspect, the thin film is a composite layer comprised of three elements with the formula M_{1P}M_{2Q}O_{R} where P, Q, and R are fractions between 0 and 1 and which together equal 1 and where M₁ and M₂ are two different metals. Preferably, the composite layer is comprised of HfO₂ and ZrO₂ monolayers and is especially useful as a gate dielectric layer in a MOSFET device.

In still another aspect, th thin film is a composite layer comprised of four elements with the formula M₁ᵥSi_{X}B_{Y}N_{Z} where M₁ is Ti, Ta, or W, and V, X, Y, and Z are fractions between 0 and 1 which together equal 1. The composite layer is comprised of M₁SiN and M₁BN monolayers and optionally may have M₁S, M₁N, and M₁B monolayers.

In yet another aspect, the thin film is a composite layer comprised of four elements with the formula M₁ᵥM_{2W}S_{X}N_{Z} where M₁ and M₂ are Ti, Ta, or W and M₁ is different than M₂ while V, W, X, and Z are fractions between 0 and 1 which together equal 1, and S is B or Si. In one example, the composite layer is comprised of M₁SiN and M₂SiN monolayers and optionally may have M₁S and M₁N monolayers. In a second example, the composite layer is comprised of M₁BN and M₂BN monolayers and optionally may have M₁B and M₁N monolayers.

In a fifth aspect, the thin film is a composite layer with five elements and has the formula M₁ᵥM_{2W}Si_{X}B_{Y}N_{Z} where M₁ and M₂ are Ti, Ta, or W and M₁ is different than M₂ while V, W, X, Y, and Z are fractions between 0 and 1 which together equal 1. In one example, the composite layer is comprised of M₁SiN and M₂BN monolayers and optionally one or more monolayers which are M₁Si, M₂B, M₁N, and M₂N. In a second example, the composite layer is comprised of M₂SiN and M₁BN monolayers and optionally one or more monolayers which are M₂Si, M₁B, M₁N and M₂N. The composite layer has other possible combinations of monolayers such as M₁Si, M₂Si, M₁BN, M₂BN and optionally one or more of M₁N, M₂N, M₁Si, M₂Si, M₁B, and M₂B layers that are formed in any order. The composite layer is especially useful as a diffusion barrier layer for a copper interconnect.

### BRIEF DESCRIPTION OF THE DRAWINGS

The features and advantages of a semiconductor device according to the present invention and further details of a process of fabricating such a device in accordance with the present invention will be more clearly understood from the following description taken in conjunction with the accompanying drawings in which like reference numerals designate similar or corresponding elements, regions, and portions and in which:

FIG. 1 is a flow diagram which depicts an ALD process according to an embodiment of the present invention that forms a layer comprised of three elements.

FIGS. 2a-2e are cross-sectional views showing the formation of a diffusion barrier layer in an opening during the fabrication of an interconnect according to an embodiment of the present invention.

FIG. 3 is a flow diagram that depicts an ALD process that forms a metal oxide layer according to the second embodiment of the present invention.

FIG. 4 is a cross-sectional view of a partially formed transistor with a gate dielectric layer formed according to the second embodiment of the present invention

FIG. 5 is a flow diagram showing an ALD process that forms a composite layer comprised of four elements according to the third embodiment of the present invention.

FIG. 6 is a flow diagram showing an ALD process that forms a composite layer with four elements according to the fourth embodiment of the present invention.

FIGS. 7a-7c are cross-sectional views showing the formation of a metal layer and diffusion barrier layer that are formed according to a fifth embodiment.

FIGS. 8a-8c are a flow diagram showing an ALD method that forms a layer comprised of five elements according to the fifth embodiment of the present invention.

### DETAILED DESCRIPTION OF THE INVENTION

The present invention is an ALD method and structure that is useful for fabricating MOSFET transistors and copper interconnects. The ALD method is especially useful in forming a thin film with excellent uniformity and a well controlled thickness and composition. The ALD deposited film is a composite layer that is comprised of three or more elements.

### First Embodiment

In a first embodiment, a composite layer comprised of three elements is applied with an ALD method and is especially useful as a diffusion barrier layer for Cu in an interconnect structure. However, the ALD deposited layer is not limited to barrier layer applications or to interconnect structures and may be used wherever a composite layer containing three elements is employed in a semiconductor device. The composite layer has the formula M_{1V}S_{X}N_{Z} where M₁ is a metal, S is Si or B, and N is nitrogen and where V, X, and Z are fractions between 0 and 1 that together equal 1.

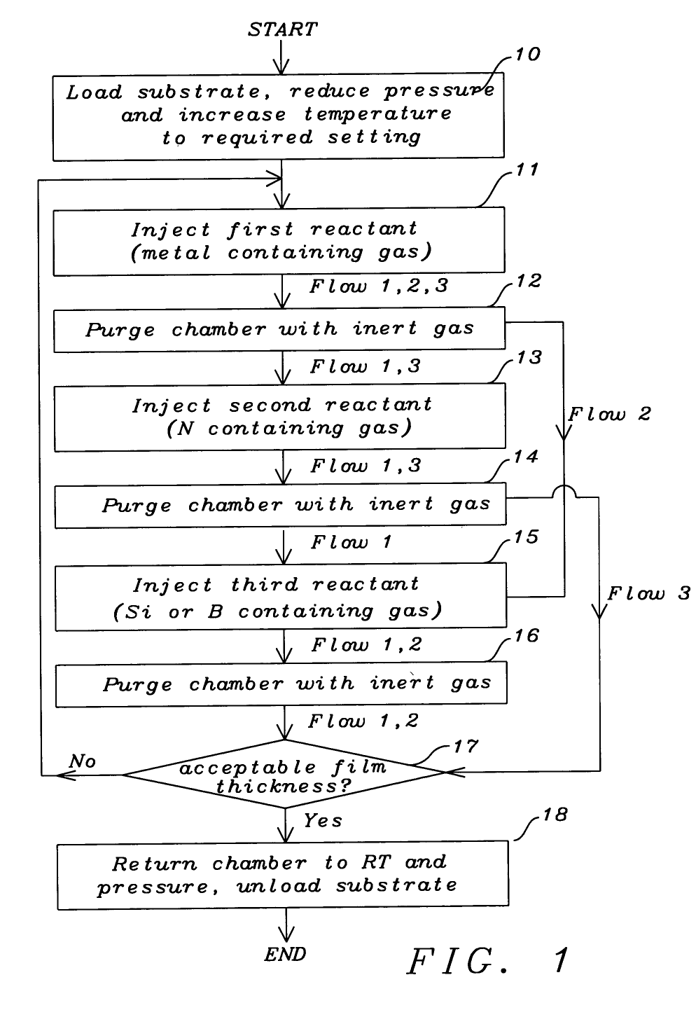

Referring to FIG. 1, a flow diagram shows a representative method for an ALD sequence comprised of a plurality of cycles that each form a monolayer and collectively form a composite layer. A substrate is provided and is loaded into a process chamber in an ALD tool in step 10. Typically, the substrate is secured to a chuck or pedestal in the process chamber. The ALD process tool may be an Endura system that is available from Applied Materials, Inc. of Santa Clara, Calif. Other ALD tools such as those available from ASM are also acceptable. Step 10 also involves heating the process chamber so that the substrate reaches a temperature in the range of 100° C. to 500° C. which is maintained until the ALD process is completed. Additionally, all gases are removed from the process chamber in step 10 by a vacuum system (not shown) which is part of the ALD tool. Pressure within the process chamber is typically less than 5 torr during subsequent steps until the substrate is removed in step 18.

Beginning with step 11, there are three possible flows to form a first monolayer that is deposited on the substrate. Each flow represents one cycle. First, flow 1 that is a series of steps in which a three element monolayer is formed will be described. In step 11, a first reactant is injected into the process chamber through a port. The first reactant is a metal (M₁) containing gas with the formula M₁L_{T} or M₁E_{U} where L is a halogen (F, Cl, Br, I) and T is an integer greater than 0 or where E is an organic moiety containing carbon (C) and hydrogen (H), or C, H and nitrogen (N), or C, H and oxygen (O) and where U is an integer >0. The metal M₁ is preferably Ta, Ti, or W. A representative source gas for Ta is Ta{N(CH₃)₂}₅ also known as PDMAT and for W is WF₆. A Ti source gas is TiCl₄ or Ti{OCH(CH₃)₂}₄ may be used if there is a concern about chloride contamination.

The first reactant is preferably injected into the process chamber at a flow rate from about 10 to 1000 standard cubic centimeters per minute (sccm) for a period of from 0.1 to 10 seconds. Optionally, the first reactant may be injected with an inert carrier gas that is Ar, He, or N₂. In step 12, an inert gas is injected into the process chamber for a period of about 0.1 to 10 seconds to sweep out any first reactant that is not absorbed on the substrate. The inert gas is Ar, He, or N₂. Optionally, a vacuum may be applied for a short period to remove unabsorbed first reactant. A monolayer of first reactant remains on the substrate.

The next step in flow 1 is depicted as step 13 and involves injecting a second reactant through a port in the chamber. The second reactant is a nitrogen source gas such as NH₃ or N₂H₄ and is flowed at a rate of between 10 and 1000 sccm for a period of 0.1 to 10 seconds. The nitrogen source gas may or may not form a monolayer on the first reactant monolayer before reacting to form a monolayer that is a metal nitride (M₁N). Step 14 is a repeat of step 12 where an inert gas is flowed through the chamber or a vacuum is applied to purge the nitrogen source gas. In this case, a monolayer of a metal nitride (M₁N) remains on the substrate.

Flow 1 continues with step 15 in which a third reactant that is a silicon or boron containing gas is injected into the chamber at a flow rate of from 10 to 1000 sccm for a period of 0.1 to 10 seconds. A preferred boron source gas is B₂H₆ and a preferred silicon source gas is SiH₄. The third reactant may or may not form a monolayer on the metal nitride monolayer before reacting with the metal nitride to form a M₁SN monolayer where S is Si or B. Unreacted third reactant is purged from the chamber by an inert gas or with a vacuum in step 16 similar to previous purge step 12. An acceptable film thickness is determined in step 17 by recording and monitoring the number of monolayers that have been deposited up to that point with the aid of a process control program in a computer that is linked to the ALD process chamber. Each monolayer has a known thickness that is approximately 1 Angstrom. A first cycle is now complete in which a monolayer of M₁SiN or M₁BN is formed.

Alternatively, a second method of forming a first monolayer on the substrate is represented by flow 2 that is comprised of a series of steps in the order 11, 12, 15, 16, 17. These steps are described in flow 1 and form a monolayer of M₁Si or M₁B.

A third method of forming a first monolayer on the substrate is represented by flow 3 which is comprised of a series of steps in the order 11, 12, 13, 14, 17. These steps are described in flow 1 and form a monolayer of M₁N.

Note that one monolayer is about 1 Angstrom thick and in order to deposit a composite layer that can serve as a diffusion barrier layer or with sufficient thickness to function in an alternative capacity in a semiconductor device, a plurality of monolayers is required. The ALD method of this embodiment forms a composite layer with sufficient thickness by performing one of several sequences. In a simplest case, flow 1 is repeated a plurality of times which is a predetermined number that forms a known thickness. Optionally, flow 1 is performed a plurality of times and flow 2 is performed a plurality of times, either in alternating fashion or otherwise to deposit a composite layer M_{1V}S_{X}N_{Z} that has an acceptable thickness. Furthermore, either a M₁SN or M₁S monolayer may be formed first on the substrate when forming a M_{1V}S_{X}N_{Z} layer.

Yet another option is to perform flow 1 a plurality of times and flow 3 a plurality of times either in alternating fashion or otherwise to deposit an acceptable thickness of an M_{1V}S_{X}N_{Z} layer. Either a M₁SN or M₁N monolayer may be formed first on the substrate. Still another alternative is to perform flow 1 a plurality of times, flow 2 a plurality of times, and flow 3 a plurality of times in predetermined order that is selected from one of many possible sequences to deposit a M_{1V}S_{X}N_{Z} layer. A M₁SN, M₁N, or M₁S monolayer may be formed first in the sequence. Note that while the sequence may be complex, it is carefully performed by entering the proper order in a program that is inputted into the computer which controls the ALD process chamber.

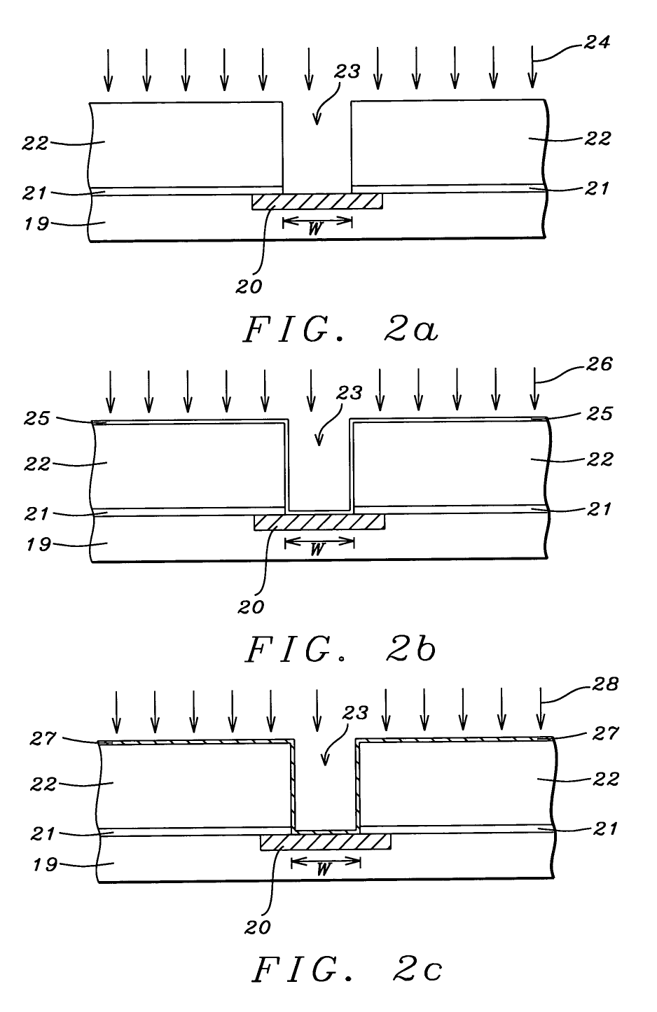

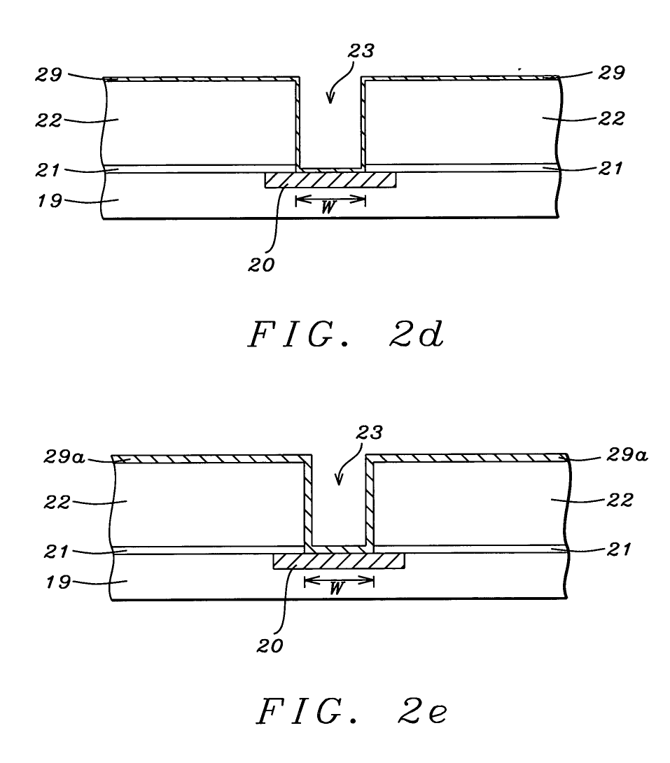

An exemplary method of applying an ALD composite layer of the first embodiment is depicted in FIGS. 2a-2e. Referring to FIG. 2a, a substrate 19 is provided that is typically silicon but may be based on silicon-germanium, gallium-arsenide or silicon-on-insulator technology. Substrate 19 typically has active and passive devices that are not shown in order to focus attention on the pertinent aspects of the invention. There is an exposed metal layer 20 contained within substrate 19. Metal layer 20 may be bounded on the sides and bottom by a diffusion barrier layer (not shown) and is separated from other metal layers that are not pictured by one or more dielectric layers (not shown).

An etch stop layer 21 is deposited by a chemical vapor deposition (CVD) or plasma enhanced CVD technique on substrate 19. Etch stop layer 21 is preferably comprised of silicon carbide, silicon oxynitride, or silicon nitride. A dielectric layer 22 is deposited on etch stop layer 21 by a CVD, plasma enhanced CVD, or spin-on method and is SiO₂ or preferably a low k dielectric material that is selected from a group including fluorine doped SiO₂, carbon doped SiO₂, polysilsesquioxanes, polyimides, and polyarylethers. Dielectric layer 22 may be annealed or treated following a deposition step to improve its properties. For example, a well known plasma treatment to densify the layer and prevent water uptake may be employed. Optionally, a cap layer (not shown) comprised of silicon nitride or silicon oxynitride is formed on dielectric layer 22 to serve as an etch stop and to provide protection for layer 22 during a subsequent planarization step.

An opening 23 that extends through dielectric layer 22 and etch stop layer 21 above metal layer 20 and which has a width w is formed by conventional means. The present invention is especially useful for forming a composite layer in openings that have a width w of about 100 nm or less. An ALD process as previously described in detail with regard to FIG. 1 is initiated by loading the substrate 19 in a process chamber in an ALD tool and heating the chamber until the substrate temperature is in a range of 100° C. to 500° C. A first reactant 24 which is a metal (M₁) containing gas is injected into the chamber and is absorbed on the sidewalls and surface of dielectric layer 22 and on the exposed surface of metal layer 20. The first reactant has the formula M₁L_{T} or M₁E_{U} as described earlier in step 11.

After a short period, the chamber is purged with an inert gas such as Ar, He, or N₂ or with a vacuum to leave a monolayer 25 of the first reactant on dielectric layer 22 and on metal layer 20 in opening 23 as depicted in FIG. 2b. A second reactant 26 that is preferably a nitrogen source gas such as NH₃ or N₂H₄ is injected into the chamber for a short period of time and reacts with the first monolayer 25 to form a monolayer 27 as shown in FIG. 2c. Unreacted second reactant is purged with an inert gas or vacuum to leave monolayer 27 which is a metal nitride on dielectric layer 22 and on metal layer 20. A third reactant 28 that is preferably a Si source gas such as SiH₄ or a B source gas such as B₂H₆ is injected into the chamber for a short period and reacts with the monolayer 27.

Referring to FIG. 2d, a monolayer 29 comprised of M₁SN where S is Si or B remains on dielectric layer 22 and on metal layer 20 after the process chamber is purged to remove excess third reactant 28. Monolayer 29 has a thickness of about 1 Angstrom which is not sufficiently thick to serve as a diffusion barrier layer that typically has a thickness in the range of 10 to 100 Angstroms. Thus, a plurality of monolayers must be formed by the ALD process to give a composite layer with the desired thickness.

In one aspect, the first embodiment is used to form a composite M_{1V}S_{X}N_{Z} layer 29a shown in FIG. 2e by depositing a series of M₁SN monolayers when performing the sequence comprised of a plurality of cycles represented as flow 1 in FIG. 1. Optionally, a composite M_{1V}S_{X}N_{Z} layer may be formed by other sequences comprised of cycles that involve flow 1 and flow 2 or flow 1 and flow 3 that were mentioned previously.

At this point, a metal interconnect (not shown) may be completed by depositing a metal layer that is preferably copper which fills opening 23 above composite layer 29a and planarizing the metal so that the metal layer in opening 23 is coplanar with the surface of dielectric layer 22. The advantage of this embodiment is that a composite layer 29a is formed which has excellent uniformity and provides the step coverage needed to form a highly conformal layer on dielectric layer 22 and in a small opening 23. Moreover, the deposition sequence is flexible to enable the user to vary the composite layer 29a so that a first portion formed early in the sequence may be enriched in one element while another portion formed later in the sequence may be enriched in a second element to optimize the properties for each portion. For example, a first portion may be optimized for adhesion to a dielectric layer while a later portion is optimized for adhesion to a copper layer. Copper barrier capability is improved over physical vapor deposition (PVD) methods in terms of a more reproducible diffusion barrier layer composition with fewer impurities. Moreover, the diffusion barrier layer formed by the first embodiment is expected to provide a longer via electromigration lifetime than a PVD method.

The present invention is also a composite layer that is formed on a substrate by an ALD method of the first embodiment. The composite layer has the formula M₁ᵥS_{X}N_{Z} where a first metal (M₁) is preferably Ti, Ta, or W and S is Si or B. The composition of the three elements is represented by the fractions V, X, and Z which are between 0 and 1 and which together equal 1.

In one example, the composite layer is comprised of a plurality of M₁SiN monolayers that optionally has one or more monolayers which are M₁Si and M₁N formed in any predetermined sequence with the M₁SiN monolayers. In a second example, the composite layer is comprised of a plurality of M₁BN monolayers that optionally has one or more monolayers which are M₁B and M₁N formed in any predetermined sequence with the M₁BN monolayers. The composite layer is formed with a thickness in the range of 10 to 100 Angstroms and is useful as a diffusion barrier layer for a Cu interconnect.

### Second Embodiment

In a second embodiment, a composite metal oxide layer comprised of three elements is applied with an ALD method and serves as a high k dielectric layer in a MOSFET device that may be a n-type (NMOS) or p-type (PMOS) transistor. The composite layer has the formula. M_{1P}M_{2Q}O_{R} where M₁ is a first metal, M₂ is a second metal, O is oxygen and where P, Q, and R are fractions between 0 and 1 that when added together equal 1.

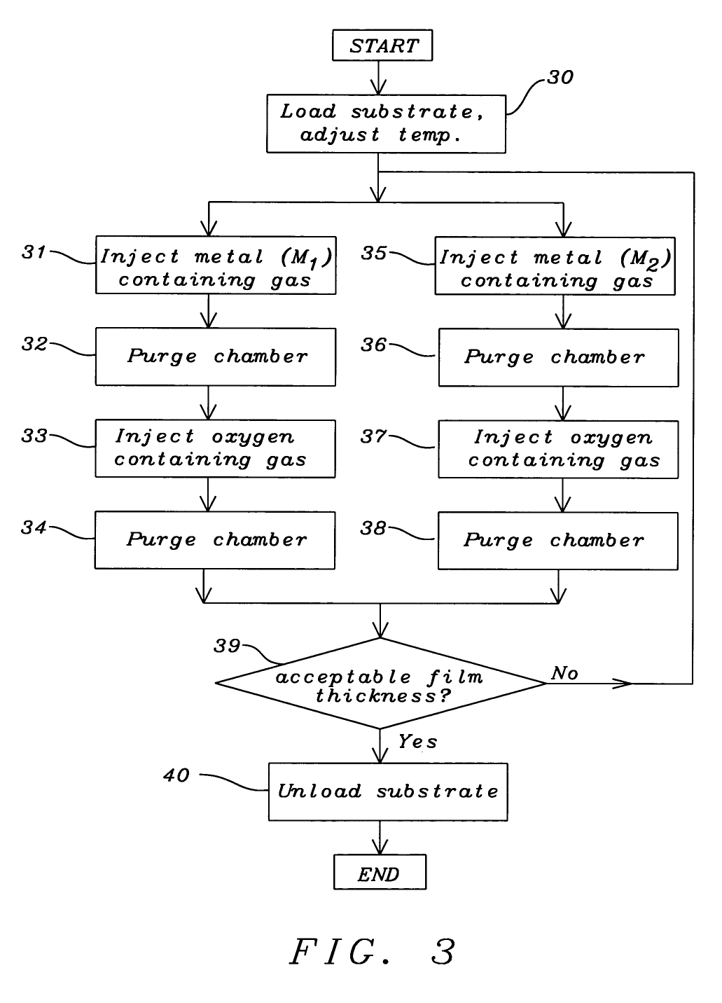

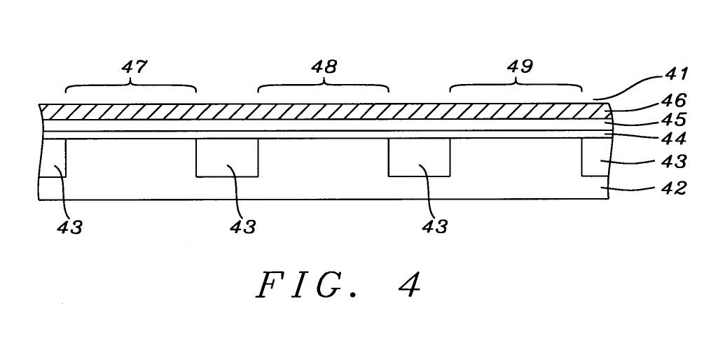

Referring to FIG. 3, a flow diagram shows a representative method for an ALD sequence that provides a composite metal oxide layer. A substrate is provided and is loaded into a process chamber in an ALD tool in step 30. Typically, the substrate is secured to a chuck or pedestal in the process chamber which is part of an ALD tool described in the first embodiment. Step 30 also involves heating the chamber so that the substrate reaches a temperature in the range of 100° C. to 500° C. which is maintained until the ALD process is completed. Additionally, all gases are removed from the chamber in step 30 by a vacuum system which is part of the ALD tool. The pressure within the chamber is kept below 5 torr during ALD deposition steps.

There are two possible cycles which can be exercised to form a first monolayer that is deposited on the substrate. Cycle M1 that forms a first metal oxide monolayer is initiated in step 31 where a first reactant which is a first metal (M₁) containing gas is injected into the process chamber through a port that might be a nozzle or showerhead. The first metal (M₁) containing gas has the formula M₁L_{T} or M₁R_{T} where L is a halogen (F, Cl, Br, I), T is an integer greater than 0, and R is an alkyl group that may contain N or O. M₁ is preferably Hf.

The first reactant is preferably injected into the chamber at a flow rate from about 10 to 1000 sccm for a period of from 0.1 to 10 seconds. In step 32, an inert gas which is Ar, He, or N₂ is injected into the chamber for a period of about 0.1 to 10 seconds to sweep out any first reactant that is not absorbed on the substrate. Optionally, a vacuum may be applied for a short period to remove unabsorbed first reactant. A monolayer of first reactant now remains on the substrate.

The next step in cycle M1 is depicted as step 33 and involves injecting a second reactant through a port in the chamber. The second reactant is an oxygen source gas such as H₂O or H₂O₂ and is flowed at a rate of between 10 and 1000 sccm for a period of 0.1 to 10 seconds. The oxygen source gas may or may not form a monolayer on the first reactant monolayer before reacting to form a monolayer that is a first metal oxide. Step 24 is a repeat of step 22 where an inert gas is flowed through the chamber or a vacuum is applied to purge the oxygen source gas. A monolayer of a first metal oxide that is preferably HfO₂ remains on the substrate. The thickness of the first monolayer is about 1 Angstrom and is not sufficiently thick to function as a high k dielectric layer which is typically about 10 to 100 Angstroms thick.

The next step in the cycle M1 is step 39. An acceptable film thickness is determined in step 39 by recording and monitoring the number of monolayers that have been deposited up to that point with the aid of a process control program in a computer that is linked to the ALD process chamber.

A second monolayer is then deposited on the first monolayer by either repeating cycle M1 or by following cycle M2 to form a second metal oxide monolayer. Cycle M2 begins with step 35 where a third reactant which is a second metal (M₂) containing gas is injected into the process chamber through a port that might be a nozzle or showerhead. The second metal (M₂) containing gas has a formula M₂L_{T} or M₂R_{T} where L is a halogen (F, Cl, Br, I), T is an integer greater than 0, and R is an alkyl group. M₂ is preferably Zr. The second metal (M₂) containing gas is preferably injected into the chamber at a flow rate from about 10 to 1000 sccm for a period of from 0.1 to 10 seconds. In step 36, the chamber is purged by a vacuum or by an inert gas which is Ar, He, or N₂ that is injected into the chamber for a period of about 0.1 to 10 seconds. A monolayer of the third reactant remains on the first metal oxide monolayer.

Step 37 which is the same as step 33 introduces an oxygen source gas into the chamber. The oxygen source gas reacts with the third reactant monolayer to form a second metal oxide monolayer that is preferably ZrO₂. In step 38, the chamber is purged by applying the same conditions as described for step 36 to remove excess oxygen source gas. Again, step 39 is executed as mentioned previously. Cycle M2 is completed at the end of step 39.

A composite metal oxide layer with the formula M_{1P}M_{2Q}O_{R} is formed by an ALD sequence with a predetermined number and order of cycles that involves performing cycle M1 a plurality of times and performing cycle M2 a plurality of times either in alternating fashion or otherwise until an appropriate thickness of monolayers is achieved. The chamber is returned to atmospheric pressure in step 40 and the substrate is removed.

An example of applying the ALD method of the second embodiment is depicted in FIG. 4. A semiconductor device 41 comprised of a substrate 42 that is typically silicon and having shallow trench isolation (STI) regions 43 is provided. Partially formed transistors 47, 48, 49 are located between STI regions 43. An interfacial layer 44 comprised of SiO₂, silicon nitride, or silicon oxynitride and with a thickness between 0 and about 30 Angstroms is deposited on substrate 42 by a CVD or PECVD technique or by a rapid thermal process. A gate dielectric layer 45 comprised of a composite metal oxide having the formula M_{1P}M_{2Q}O_{R} is then formed by an ALD method of the second embodiment. Preferably, the composite layer is comprised of HfO₂ and ZrO₂ monolayers and has a thickness from about 15 to 100 Angstroms. A high k gate dielectric layer 45 which is a composite of ZrO₂ and HfO₂ is preferred over a traditional SiO₂ gate oxide because ZrO₂ and HfO₂ serve as a better barrier in suppressing tunneling current and thereby reduce gate leakage current. High k gate dielectric layer 45 is preferred over a ZrO₂ or a HfO₂ layer since a composite layer is non-periodic and thereby has less of a grain boundary which makes electron tunneling more difficult.

A gate layer 46 that is typically doped or undoped polysilicon is deposited by a conventional method on high k gate dielectric layer 45. Transistors 47, 48, 49 are completed by methods known to those skilled in the art and will not be described herein. The ALD method of this invention has an advantage over PVD and PECVD methods since the gate dielectric layer is deposited in a more uniform manner and with fewer impurities. Moreover, the composition of Hf and Zr can be varied throughout the sequence. For example, the ratio P/Q may be increased in one portion of the ALD sequence and decreased in another portion to optimize properties such as adhesion and barrier performance at different depths within the high k gate dielectric layer 45.

The present invention is also a composite layer that is formed on a substrate by an ALD method of the second embodiment. The composite layer has the formula M_{1P}M_{2Q}O_{R} where a first metal (M₁) is preferably Hf and a second metal (M₂) is preferably Zr. The composition of the three elements is represented by the fractions P, R, and Q which are between 0 and 1 and which together equal 1.

The composite layer is comprised of a plurality of first metal oxide monolayers and second metal oxide monolayers which are formed in any predetermined sequence. The composite layer is formed with a thickness in the range of 10 to 100 Angstroms and is especially useful as a gate dielectric layer in a MOSFET device.

### Third Embodiment

In a third embodiment, a composite layer comprised of four elements is formed by an ALD method. In one aspect, the composite layer serves as a diffusion barrier layer in a Cu interconnect scheme. However, the ALD deposited layer is not limited to barrier layer applications or to interconnect structures and may be employed in any semiconductor device where a composite layer containing four elements is useful. The composite layer has the formula M₁ᵥM_{2W}S_{X}N_{Z} where M₁ is a first metal, M₂ is a second metal, S is Si or B, and N is nitrogen and where V, W, X, and Z are fractions between 0 and 1 and which added together equal 1.

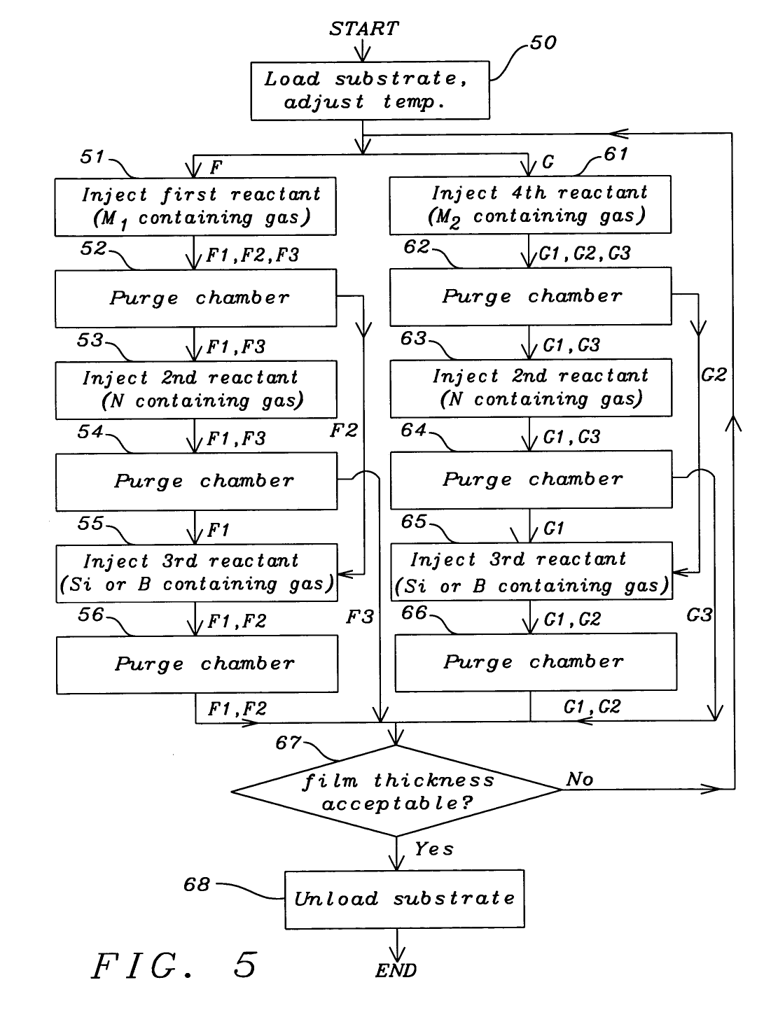

Referring to FIG. 5, a flow diagram shows a method including a cycle F and a cycle G that may be performed in various orders in an ALD sequence to deposit a composite layer comprised of four elements. A substrate is loaded into a process chamber in an ALD tool in step 50 and the chamber is prepared for processing as described in step 30.

Beginning with step 51, there are three possible flows within cycle F to form a first monolayer that is deposited on the substrate. Each flow represents one cycle. First, flow F1 that is a series of steps in which a three element monolayer is formed will be described. In step 51, a first reactant is injected into the process chamber through a port such as a nozzle or showerhead. The first reactant is a metal (M₁) containing gas with the formula M₁L_{T} or M₁E_{U} where L is a halogen (F, Cl, Br, I) and T is an integer greater than 0 or where E is an organic moiety containing C and H, or C, H, and N, or C, H and O and where U is an integer >0. The metal M₁ is preferably Ta, Ti, or W. A representative source gas for Ta is PDMAT or TaCl₄ and for W is WF₆. Representative Ti source gases are TiCl₄ and TiF₄ or Ti{OCH(CH₃)₂}₄ may be employed if there is a concern about halide contamination.

The first reactant is preferably injected into the chamber at a flow rate from about 10 to 1000 sccm for a period of from 0.1 to 10 seconds. Optionally, the first reactant may be injected with an inert carrier gas that is Ar, He, or N₂. In step 52, an inert gas which is Ar, He, or N₂ is injected into the chamber for a period of about 0.1 to 10 seconds to sweep out any first reactant that is not absorbed on the substrate. Optionally, a vacuum may be applied for a short period to remove unabsorbed first reactant. A monolayer of first reactant now remains on the substrate.

The next step in flow F1 is depicted as step 53 and involves injecting a second reactant through a port in the chamber. The second reactant is a nitrogen source gas such as NH₃ or N₂H₄ and is flowed at a rate of between 10 and 1000 sccm for a period of 0.1 to 10 seconds. The nitrogen source gas may or may not form a monolayer on the first reactant monolayer before reacting to form a monolayer that is a metal nitride. Step 54 is a repeat of step 52 where an inert gas is flowed through the chamber or a vacuum is applied to purge the nitrogen source gas. A monolayer of a metal nitride (M₁N) remains on the substrate.

Flow F1 continues with step 55 in which a third reactant comprised of a silicon or boron containing gas is injected into the chamber at a flow rate of from 10 to 1000 sccm for a period of 0.1 to 10 seconds. A preferred boron source gas is B₂H₆ and a preferred silicon source gas is SiH₄. The third reactant may or may not form a monolayer on the metal nitride monolayer before reacting with the metal nitride to form a M₁SN monolayer where S is Si or B. The third reactant is purged from the chamber by an inert gas or with a vacuum in step 56 similar to previous purge step 52. A first cycle is completed in step 67. An acceptable film thickness is determined in step 67 by recording and monitoring the number of monolayers that have been deposited up to that point with the aid of a process control program in a computer that is linked to the ALD chamber.

Alternatively, a second method of forming a first monolayer on the substrate in a cycle F is represented by flow F2 which is comprised of a series of steps in the order 51, 52, 55, 56, 67. These steps are described in flow F1 and form a monolayer of M₁Si or M₁B on the substrate.

A third method of forming a first monolayer on the substrate in a cycle F is represented by flow F3 which is comprised of a sequence of steps in the order 51, 52, 53, 54, 67. These steps are described in flow F1 and form a monolayer of M₁N.

Beginning with step 61, there are three possible flows within cycle G to form a first monolayer that is deposited on the substrate. Each flow represents one cycle. First, flow G1 that is a series of steps in which a three element monolayer is formed will be described. In step 61, a fourth reactant is injected into the process chamber through a port. The fourth reactant is a metal (M₂) containing gas with the formula M₂L_{T} or M₂E_{U} where L is a halogen (F, Cl, Br, I) and T is an integer >0 or where E is an organic moiety containing C and H, or C, H, and N, or C, H and O and where U is an integer >0. The metal M₂ is preferably Ta, Ti, or W and is different than metal M₁.

The fourth reactant is preferably injected into the chamber at a flow rate from about 10 to 1000 sccm for a period of from 0.1 to 10 seconds. Optionally, the fourth reactant may be injected with an inert carrier gas that is Ar, He, or N₂. In step 62, a vacuum is applied or an inert gas which is Ar, He, or N₂ is injected into the chamber for a period of 0.1 to 10 seconds to sweep out any fourth reactant that is not absorbed on the substrate. A monolayer of fourth reactant remains on the substrate.

The next step in flow G1 is depicted as step 63 and involves injecting a second reactant through a port in the chamber. The second reactant is a nitrogen source gas such as NH₃ or N₂H₄ and is flowed at a rate of between 10 and 1000 sccm for a period of 0.1 to 10 seconds. Step 64 is a repeat of step 62 where an inert gas is flowed through the chamber or a vacuum is applied to purge the nitrogen source gas. A monolayer of a metal nitride (M₂N) remains on the substrate.

Flow G1 continues with step 65 in which a third reactant comprised of a silicon or boron containing gas is injected into the chamber at a flow rate of from 10 to 1000 sccm for a period of 0.1 to 10 seconds. A preferred boron source gas is B₂H₆ and a preferred silicon source gas is SiH₄. The third reactant is purged from the chamber by an inert gas or with a vacuum in step 66 similar to previous purge step 62. A first cycle is now completed in step 67.

Alternatively, a second method of forming a first monolayer on the substrate in a cycle G is represented by flow G2 which is comprised of a series of steps in the order 61, 62, 65, 66, 67. These steps are described in flow G1 and form a monolayer of M₂S or M₂B. A third method of forming a first monolayer on the substrate in a cycle G is represented by flow G3 which is comprised of a series of steps in the order 61, 62, 63, 64, 67. These five steps are described in flow G1 and form a monolayer of M₂N.

In order to deposit a composite layer of M₁ᵥM_{2W}S_{X}N_{Z} that can serve as a diffusion barrier layer or with sufficient thickness to function in an alternative capacity in a semiconductor device, a plurality of monolayers is required. The ALD method of this embodiment forms a composite layer with sufficient thickness by following one of several sequences that have a predetermined order and number of cycles. Each sequence involves performing cycle F a plurality of times and performing cycle G a plurality of times in either an alternating manner or otherwise. Furthermore, each cycle F may be comprised of a flow F1, F2, or F3 and each cycle G may be comprised of a flow G1, G2 or G3. When an acceptable film thickness is reached, the substrate is unloaded in step 68 and is ready for subsequent processing. Either cycle F or cycle G may be performed to deposit a first monolayer. Although the sequence may be complex, it is carefully controlled by entering the proper order in a program that is inputted into the computer that is linked to the ALD process chamber.

The ALD sequence is flexible to enable the user to vary the composite layer so that a first portion formed early in the sequence may be enriched in one metal or element while another portion formed later in the sequence may be enriched in a second metal or element to optimize the properties for each portion. For example, a first portion may be optimized for adhesion to a dielectric layer while a later portion is optimized for adhesion to a copper layer. Copper barrier capability is improved over CVD methods in terms of a more reproducible diffusion barrier layer composition with fewer impurities.

The present invention is also a composite layer that is formed on a substrate by an ALD method of the third embodiment. The composite layer has the formula M₁ᵥM_{2W}S_{X}N_{Z} where a first metal (M₁) and a second metal (M₂) are preferably selected from the group Ti, Ta, and W and M₁ is unequal to M₂ and where S is Si or B. The composition of the four elements is represented by the fractions V, W, X, and Z which are between 0 and 1 and which together equal 1.

In one example, the composite layer is comprised of a plurality of M₁SiN and M₂SiN monolayers that optionally has one or more monolayers which are M₁Si, M₂Si, and M₁N which are formed in any sequence with the M₁SiN and M₂SiN monolayers. In a second example, the composite layer is comprised of a plurality of M₁BN and M₂BN monolayers that optionally has one or more monolayers which are M₁B, M₂B, and M₁N formed in any sequence with the M₁BN and M₂BN monolayers. The composite layer is formed with a thickness in the range of 10 to 100 Angstroms and is especially useful as a diffusion barrier layer for a copper interconnect.

### Fourth Embodiment

In a fourth embodiment, a composite layer comprised of four elements is formed by an ALD method. In one aspect, the composite layer serves as a diffusion barrier layer in a Cu interconnect scheme. However, the ALD deposited layer is not limited to barrier layer applications or to interconnect structures and may be employed in any semiconductor device where a layer containing four elements is employed. The composite layer is comprised of a metal M₁, silicon, boron, and nitrogen and has the formula M₁ᵥSi_{X}B_{Y}N_{Z} where V, X, Y, and Z are fractions between 0 and 1 and which added together equal 1.

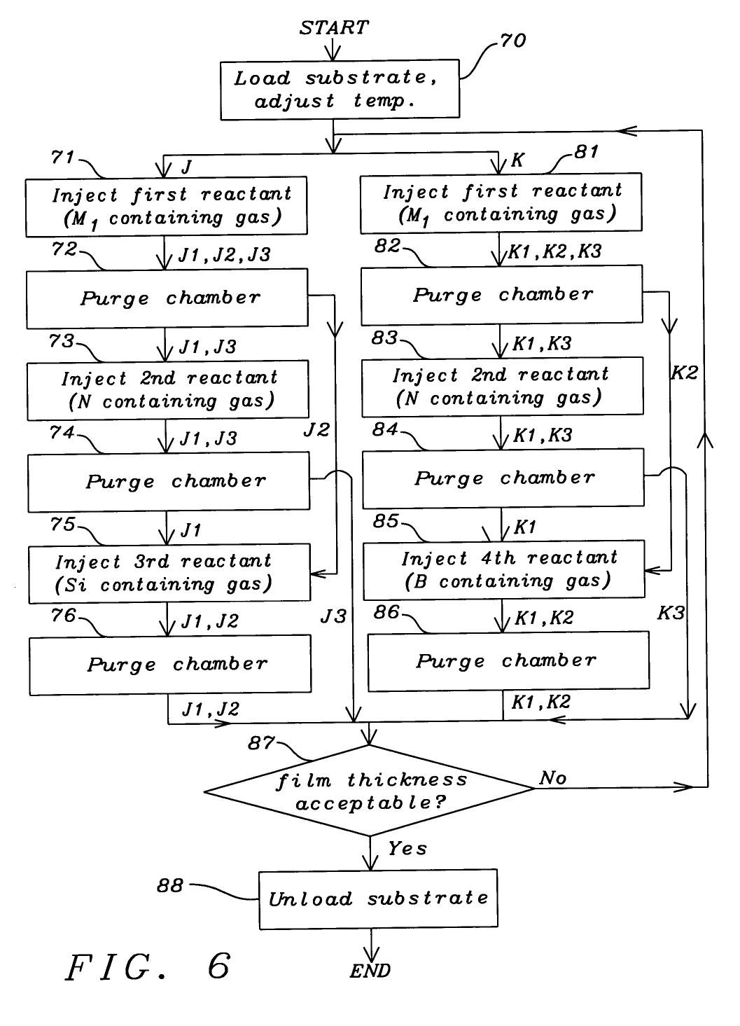

Referring to FIG. 6, a flow diagram shows a method including a cycle J and a cycle K that may be performed in various orders in an ALD sequence with a predetermined order and number of cycles to deposit a composite layer comprised of four elements. A substrate is loaded into a process chamber in an ALD tool in step 70. Temperature and pressure conditions are stabilized as described in the third embodiment and all gases are removed by a vacuum system.

Beginning with step 71, there are three possible flows within cycle J to form a first monolayer that is deposited on the substrate. Each flow represents one cycle. First, flow J1 that is a series of steps in which a three element monolayer is formed will be described. In step 71, a first reactant is injected into the process chamber through a port. The first reactant is a metal (M₁) containing gas with the formula M₁L_{T} or M₁E_{U} as described previously. The metal M₁ is preferably Ta, Ti, or W.

The first reactant is preferably injected into the chamber at a flow rate from about 10 to 1000 sccm for a period of from 0.1 to 10 seconds. Optionally, the first reactant may be injected with an inert carrier gas that is Ar, He, or N₂. In step 72, an inert gas which is Ar, He, or N₂ is injected into the chamber for a period of 0.1 to 10 seconds to sweep out any first reactant that is not absorbed on the substrate. Optionally, a vacuum may be applied for a short period to remove unabsorbed first reactant. A monolayer of first reactant remains on the substrate.

The next step in flow J1 is depicted as step 73 and involves injecting a second reactant through a port in the chamber. The second reactant is a nitrogen source gas such as NH₃ or N₂H₄ and is flowed at a rate of between 10 and 1000 sccm for a period of 0.1 to 10 seconds. The nitrogen source gas may or may not form a monolayer on the first reactant monolayer before reacting with the first reactant to form a monolayer that is a metal nitride. Step 74 is a repeat of step 72 where an inert gas is flowed through the chamber or a vacuum is applied to purge the nitrogen source gas. A monolayer of a metal nitride (M₁N) remains on the substrate.

Flow J1 continues with step 75 in which a third reactant comprised of a silicon containing gas is injected into the chamber at a flow rate of from 10 to 1000 sccm for a period of 0.1 to 10 seconds. A preferred silicon source gas is SiH₄ although Si(OCH₃)₄ and Si(OC₂H₅)₄ are other Si source gases. The third reactant may or may not form a monolayer on the M₁N monolayer before reacting with the metal nitride to form a M₁ SiN monolayer. The third reactant is purged from the chamber by an inert gas or with a vacuum in step 76 similar to previous purge step 72. A first cycle is completed in step 87. An acceptable film thickness is determined in step 87 by recording and monitoring the number of monolayers that have been deposited up to that point with the aid of a process control program in a computer that is linked to the ALD chamber.

Alternatively, a second method of forming a first monolayer on the substrate in a cycle J is represented by flow J2 which is comprised of a series of steps in the order 71, 72, 75, 76, 87. These steps are described in flow J1 and form a monolayer of M₁Si.

A third method of forming a first monolayer on the substrate in a cycle J is represented by flow J3 which is comprised of a series of steps in the order 71, 72, 73, 74, 87. These steps are described in flow J1 and form a monolayer of M₁N.

Beginning with step 81, there are three possible flows within cycle K to form a first monolayer that is deposited on the substrate. Each flow represents one cycle. First, flow K1 that is a series of steps in which a three element monolayer is formed will be described. In step 81, the first reactant is injected into the process chamber through a port. The first reactant is a metal (M₁) containing gas whose composition and injection conditions are the same as described in step 71. Step 82 involves purging the chamber by injecting Ar, He, or N₂ for a period of 0.1 to 10 seconds or with a vacuum. A monolayer of first reactant remains on the substrate.

The next step in flow K1 is depicted as step 83 and involves injecting the second reactant through a port in the chamber. The second reactant is a nitrogen source gas such as NH₃ or N₂H₄ and is flowed at a rate of between 10 and 1000 sccm for a period of 0.1 to 10 seconds. Step 84 is a repeat of step 82 where an inert gas is flowed through the chamber or a vacuum is applied to purge the nitrogen source gas. A monolayer of a metal nitride (M₁N) remains on the substrate.

Flow K1 continues with step 85 in which a fourth reactant comprised of a boron containing gas is injected into the chamber at a flow rate of from 10 to 1000 sccm for a period of 0.1 to 10 seconds. A preferred boron source gas is B₂H₆. Optionally, BH₃ may be used. The fourth reactant may or may not form a monolayer on the M₁N monolayer before reacting with the metal nitride to form a M₁BN monolayer. The fourth reactant is purged from the chamber by an inert gas or with a vacuum in step 86 similar to previous purge step 82. A first cycle is completed in step 87.

Alternatively, a second method of forming a first monolayer on the substrate in a cycle K is represented by flow K2 which is comprised of a series of steps in the order 81, 82, 85, 86, 87. These steps are described in flow K1 and form a monolayer of M₁B.

A third method of forming a first monolayer on the substrate in a cycle K is represented by flow K3 which is comprised of a series of steps in the order 81, 82, 83, 84, 87. These steps are described in flow K1 and form a monolayer of M₁N.

In order to deposit a composite layer of M₁ᵥS_{X}B_{Y}N_{Z} that can serve as a diffusion barrier layer or with sufficient thickness to function in an alternative capacity in a semiconductor device, a plurality of monolayers is required. The ALD method of this embodiment forms a composite layer with sufficient thickness by following one of several sequences. Each sequence involves performing cycle J a plurality of times and performing cycle K a plurality of times in either an alternating manner or otherwise. Furthermore, each cycle J is comprised of a flow J1, J2, or J3 and each cycle K is comprised of a flow K1, K2 or K3. When a predetermined number of monolayers have been deposited according to step 87, then the chamber is returned to atmospheric pressure and the substrate is unloaded in step 88. Either cycle J or cycle K may be performed to deposit a first monolayer.

The ALD sequence is flexible to enable the user to vary the composite layer so that a first portion formed early in the sequence may be enriched in one element while another portion formed later in the sequence may be enriched in a second element to optimize the properties for each portion. Copper barrier capability is improved over CVD methods in terms of a more reproducible diffusion barrier layer composition with fewer impurities. In some cases, both Si and B are desirable in a diffusion barrier layer to improve barrier layer adhesion and performance.

The present invention is also a composite layer that is formed on a substrate by an ALD method of the fourth embodiment. The composite layer has the formula M₁ᵥSi_{X}B_{Y}N_{Z} where a metal (M₁) is preferably Ti, Ta, or W. The composition of the four elements is represented by the fractions V, X, Y, and Z which are between 0 and 1 and which together equal 1. In one example, the composite layer is comprised of a plurality of M₁SiN and M₁BN monolayers that optionally have one or more monolayers which are M₁Si, M₁B, and M₁N formed in any sequence with the M₁SiN and M₁BN monolayers. The composite layer is formed with a thickness in the range of 10 to 100 Angstroms and is especially useful as a diffusion barrier layer for a copper interconnect.

### Fifth Embodiment

In the fifth embodiment, a composite layer comprised of five elements is formed by an ALD method. This embodiment offers more flexibility in tuning the properties of a composite layer by providing a method for incorporating two different metals and three additional elements (B, Si, N) in different compositions within different portions of the composite layer. In one aspect, the composite layer serves as a diffusion barrier layer in an interconnect scheme. However, the ALD deposited layer is not limited to barrier layer applications or to interconnect structures and may be employed in any semiconductor device where a layer containing five elements may offer an advantage over conventional layers with two or three elements. The composite layer has the formula M₁ᵥM_{2W}Si_{X}B_{Y}N_{Z} where V, W, X, Y, and Z are fractions between 0 and 1 and which added together equal 1.

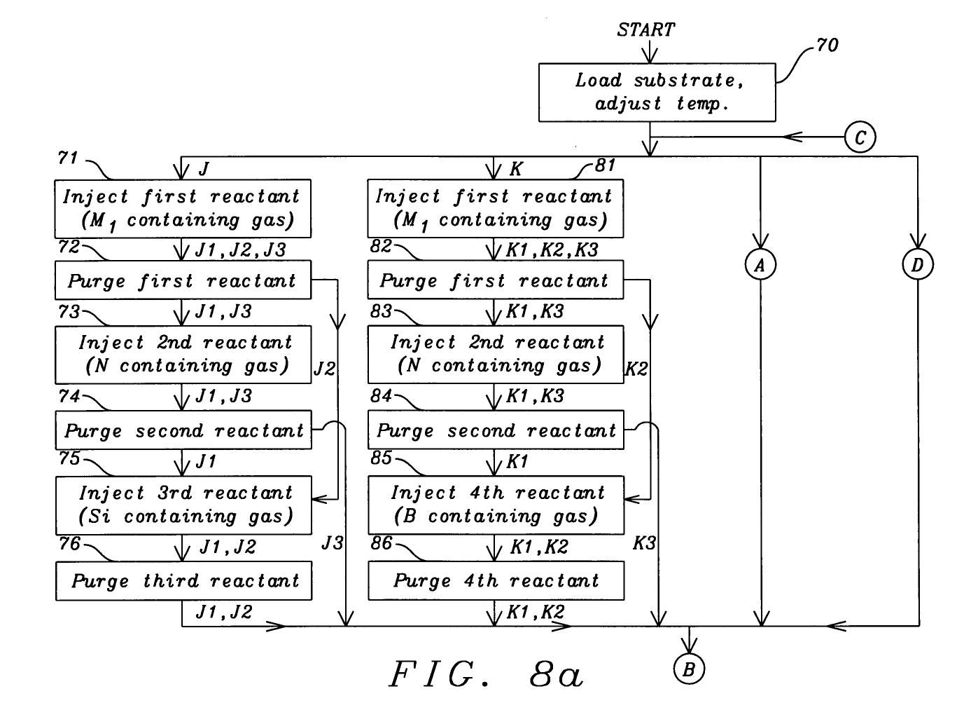

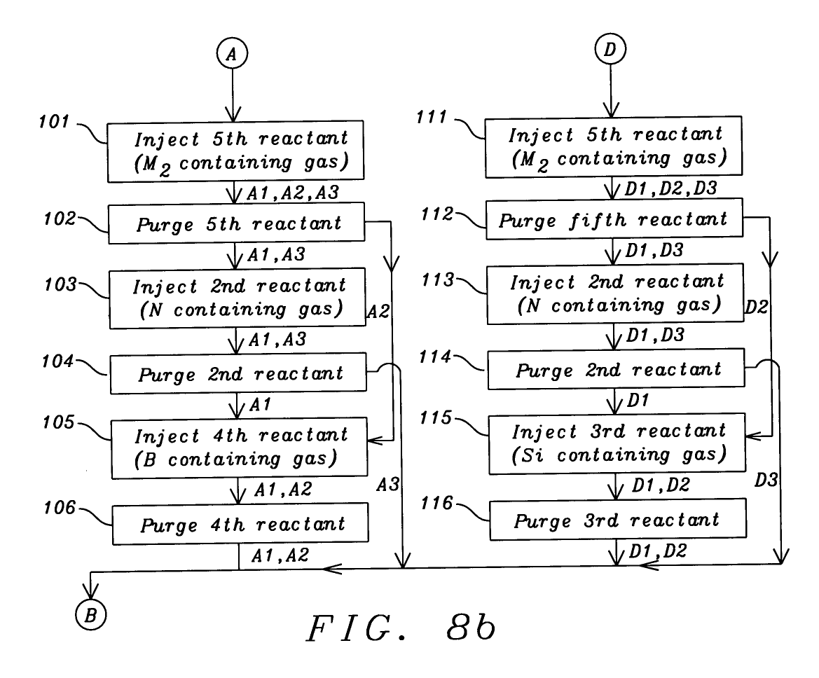

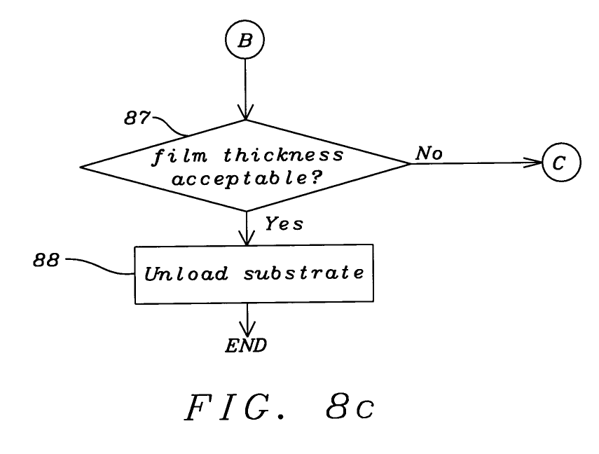

Referring to FIGS. 8a-c, a flow diagram shows a method including cycles J, K, A, and D in which two or more of the four cycles may be performed in predetermined order and number of cycles in an ALD sequence to deposit a composite layer comprised of five elements. A substrate is loaded into a process chamber in an ALD tool in step 70 and the chamber is prepared for processing as in step 30.

Cycles J and K were described in detail in the fourth embodiment and employ the same four reactants in a like manner in the fifth embodiment. Within a cycle A shown in FIG. 8b beginning with step 101, there are three possible flows to form a first monolayer that is deposited on the substrate. Each flow represents one cycle. First, flow A1 that is a series of steps in which a three element monolayer is formed will be described. In step 101, a fifth reactant is injected into the process chamber through a port such as a nozzle or showerhead. The fifth reactant is a metal (M₂) containing gas with the formula M₂L_{T} or M₂E_{U} as described earlier. The metal M₂ is preferably Ta, Ti, or W and is different than metal M₁ selected for cycles J and K. Therefore, if Ta is selected for metal M₁, W or Ti is used for metal M₂. Representative source gases for Ta, Ti, and W were described earlier in the first through fourth embodiments.

The fifth reactant is preferably injected into the chamber at a flow rate from 10 to 1000 sccm for a period of from 0.1 to 10 seconds. Optionally, the fifth reactant may be injected with an inert carrier gas that is Ar, He, or N₂. In step 102, an inert gas which is Ar, He, or N₂ is injected into the chamber for a period of 0.1 to 10 seconds to sweep out any fifth reactant that is not absorbed on the substrate. Optionally, a vacuum may be applied for a short period to remove unabsorbed fifth reactant. A monolayer of fifth reactant now remains on the substrate.

The next step in flow A1 is depicted as step 103 and involves injecting the second reactant through a port in the chamber. The second reactant is a nitrogen source gas such as NH₃ or N₂H₄ and introduced as described in step 13 of the first embodiment. Step 104 is a repeat of step 102 where an inert gas is flowed through the chamber or a vacuum is applied to purge the nitrogen source gas. A monolayer of a metal nitride (M₂N) remains on the substrate.

Flow A1 continues with step 105 in which the fourth reactant which is a boron containing gas is injected into the chamber as in step 85 of the fourth embodiment and reacts to form a M₂BN monolayer. Excess fourth reactant is purged from the chamber by an inert gas or with a vacuum in step 106 similar to a previous purge step 102. A cycle is completed in step 87.

Alternatively, a second method of forming a first monolayer on the substrate in a cycle A is represented by flow A2 which is comprised of a series of steps in the order 101, 102, 105, 106, 87. These steps are described in flow A1 and form a M₂B monolayer. A third method of forming a first monolayer on the substrate in a cycle A is represented by flow A3 which is comprised of a series of steps in the order 101, 102, 103, 104, 87. These steps are described in flow A1 and form a monolayer of M₂N.

Beginning with step 111, there are three possible flows within cycle D to form a first monolayer that is deposited on the substrate. Each flow represents one cycle. First, flow D1 that is a series of steps in which a three element monolayer is formed will be described. In step 111, the fifth reactant is injected into the process chamber through a port. The fifth reactant is a metal (M₂) containing gas whose composition and injection conditions are the same as described in step 101. Step 102 involves purging the chamber by injecting Ar, He, or N₂ for a period of 0.1 to 10 seconds or with a vacuum. A monolayer of fifth reactant remains on the substrate.

The next step in flow D1 is depicted as step 113 and involves injecting the second reactant through a port in the chamber. The second reactant is a nitrogen source gas whose composition and injection conditions are the same as those described in step 13. Step 114 is a repeat of step 112 where an inert gas is flowed through the process chamber or a vacuum is applied to purge the nitrogen source gas. A monolayer of a metal nitride (M₂N) remains on the substrate.

Flow D1 continues with step 115 in which the third reactant that is a silicon containing gas is injected into the chamber at a flow rate of from 10 to 1000 sccm for a period of 0.1 to 10 seconds. The third reactant is purged from the chamber by an inert gas or with a vacuum in step 116 similar to a previous purge step 112. A cycle is completed in step 87.

Alternatively, a second method of forming a first monolayer on the substrate in a cycle D is represented by flow D2 which is comprised of a series of steps in the order 111, 112, 115, 116, 87. These steps are described in flow D1 and form a monolayer of M₂Si. A third method of forming a first monolayer on the substrate in a cycle D is represented by flow D3 which is comprised of a series of steps in the order 111, 112, 113, 114, 87. These steps are described in flow D1 and form a monolayer of M₂N.

In order to deposit a composite layer of M₁ᵥM_{2W}Si_{X}B_{Y}N_{Z} that can serve as a diffusion barrier layer or with sufficient thickness to function in an alternative capacity in a semiconductor device, a plurality of monolayers is required. The ALD method of this embodiment forms a composite layer with sufficient thickness by following one of several sequences. One group of possible sequences involves only two of the cycles. For example, a composite layer of M₁ᵥM_{2W}Si_{X}B_{Y}N_{Z} may be formed by performing cycle J a plurality of times and performing cycle A a plurality of times in any order. Furthermore, each cycle J may be comprised of a flow J1, J2, or J3 and each cycle A may be comprised of a flow A1, A2, or A3. Alternatively, the composite layer is formed by performing cycle K a plurality of times and cycle D a plurality of times in any order. In any cycle K, a flow K1, K2, or K3 may be followed and in any cycle D, a flow D1, D2, or D3 may be followed. An acceptable thickness is recognized in a step 87 by completing a predetermined number of cycles that are known to provide a sufficient thickness. The substrate is then unloaded from the chamber in step 88.

Another group of possible sequences to form a composite layer of M₁ᵥM_{2W}Si_{X}B_{Y}N_{Z} involves any three of the cycles J, K, A, or D. For example, cycles J, K, and A are each performed a plurality of times in any order. Still another group of possible sequences involves all four cycles J, K, A, and D that are executed a plurality of times in any order. Each cycle is performed by following one of three possible flows as noted previously.

The ALD sequence is flexible to enable the user to vary the composite layer so that a first portion formed early in the sequence may be enriched in one or more elements while another portion formed later in the sequence may be enriched in other elements to optimize the properties for each portion. Copper barrier capability is improved over CVD methods in terms of a more reproducible diffusion barrier layer composition with fewer impurities.

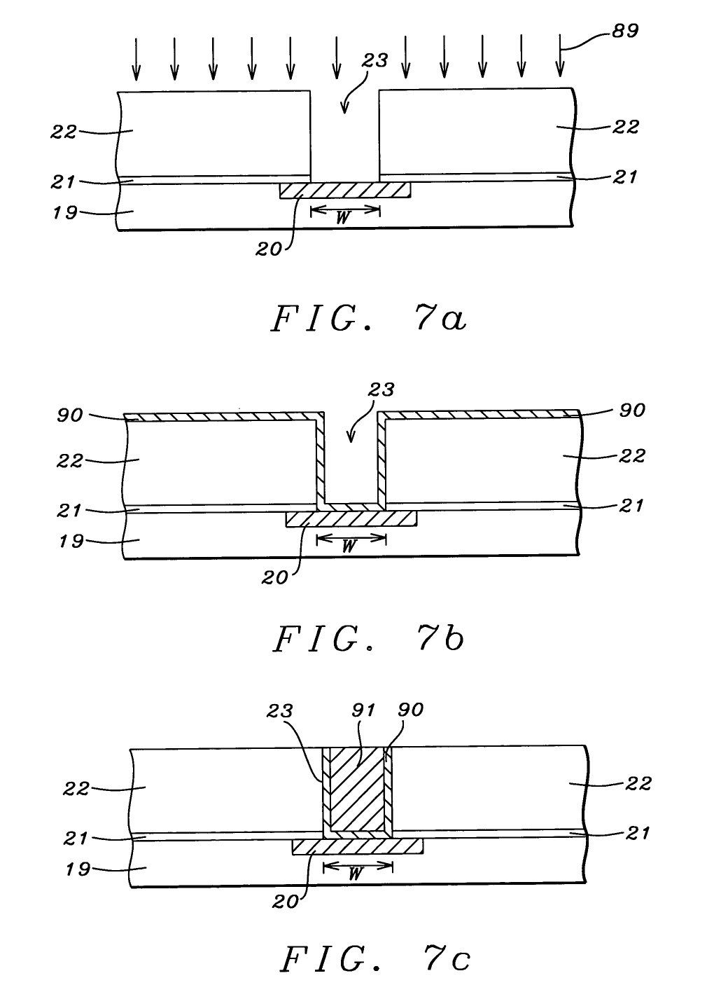

A method of applying the present invention is illustrated in FIGS. 7a-7c in which a substrate 19, metal layer 20, etch stop layer 21, and dielectric layer 22 with an opening 23 are provided as described in the first embodiment. Referring to FIG. 7a, an ALD process 89 is performed in a chamber by employing one of the possible sequences involving various cycles and flows described in the fifth embodiment to form a composite layer of M₁ᵥM_{2W}Si_{X}B_{Y}N_{Z} with a thickness of about 10 to 100 Angstroms.

Referring to FIG. 7b, a diffusion barrier layer 90 is formed as a result of ALD process 89. The barrier layer 90 forms a conformal coating on the top and sidewalls of dielectric layer 22 and on the surface of metal layer 20 in opening 23. In FIG. 7c, a metal layer 91 that is preferably copper is deposited by conventional means. The metal layer 91 is planarized by a method such as a chemical mechanical polish (CMP) step so that it is coplanar with dielectric layer 22. Diffusion barrier layer 90 on the top surface of dielectric layer 22 is removed during the planarization step. The interconnect structure shown in FIG. 7c is more reliable and has a higher performance than in prior art since the diffusion barrier layer has a more uniform thickness, contains fewer impurities, and has properties that can be optimized by varying the content and location of various elements within the composite layer of M₁ᵥM_{2W}S_{X}B_{Y}N_{Z}.

The present invention is also a composite layer that is formed on a substrate by an ALD method of the fifth embodiment. The composite layer has the formula M₁ᵥM_{2W}Si_{X}B_{Y}N_{Z} where a first metal (M₁) and a second metal (M₂) are preferably Ti, Ta, or W and M₁ is unequal to M₂. The composition of the five elements is represented by the fractions V, W, X, Y, and Z which are between 0 and 1 and which together equal 1.

In one example, the composite layer is comprised of M₁SiN and M₂BN monolayers and optionally one or more monolayers which are M₁Si, M₂B, M₁N, and M₂N that are formed in any sequence. In a second example, the composite layer is comprised of M₂SiN and M₁BN monolayers and optionally one or more monolayers which are M₂Si, M₁B, M₁N and M₂N that are formed in any sequence. In a third example, the composite layer is formed from three different monolayers selected from the group of M₁SiN, M₁BN, M₂SiN, and M₂BN monolayers and optionally one or more two element monolayers containing the same elements as in the three ternary monolayers. Moreover, the aforementioned ternary and two element monolayers in the third example may be formed in any sequence. A fourth example is a composite layer that includes all four ternary monolayers M₁SiN, M₂SiN, M₁BN, M₂BN and optionally one or more of the possible two element monolayers. The composite layer is formed with a thickness in the range of 10 to 100 Angstroms and is especially useful as a diffusion barrier layer for a copper interconnect structure as depicted in FIG. 7c.

While this invention has been particularly shown and described with reference to, the preferred embodiments thereof, it will be understood by those skilled in the art that various changes in form and details may be made without departing from the spirit and scope of this invention.

1. A thin film manufacturing method comprising:
(a) loading a semiconductor substrate into a atomic layer deposition (ALD) process chamber and bringing said ALD process chamber to an acceptable temperature and pressure;
(b) performing a cycle of steps a plurality of times in said process chamber to yield an acceptable thickness of a composite layer on said substrate, said composite layer having the formula M_{1V}S_{X}N_{Z} where V, X, and Z are fractions between 0 and 1 which together equal 1, and where S is Si or B, and wherein said steps include:
(1) injecting a first reactant comprised of a metal (M₁) containing gas for a short interval and purging said first reactant;
(2) injecting a second reactant that is an oxygen source gas for a short interval and purging said second reactant;
(3) injecting a third reactant that is a Si or B source gas for a short interval and purging said third reactant; and
(4) recording and monitoring the number of monolayers that have been deposited in said ALD process;
and wherein said cycle of steps is defined as a first flow sequence (1), (2), (3), (4) which forms a M₁SiN or M₁BN monolayer, or a second flow sequence (1), (2), (4) that forms an M₁N monolayer, or a third flow sequence (1), (3), (4) that forms an M₁B or M₁Si monolayer; said first, second, and third flow sequences are performed in any predetermined order; and
(c) returning said process chamber to atmospheric pressure and unloading said substrate from said process chamber.

2. The method of claim 1 wherein bringing said ALD process chamber to an acceptable temperature and pressure comprises applying a vacuum to remove any resident gases and heating said ALD process chamber to a temperature between about 100° C. and 500° C.

3. The method of claim 1 wherein said first reactant is injected at a flow rate of about 10 to 1000 standard cubic centimeters per minute (sccm) for a period of about 0.1 to 10 seconds and has the formula M₁L_{T} or M₁E_{U} wherein M₁ is Ta, Ti, or W, and where L is a halogen (F, Cl, Br, I) and T is an integer >0, and where E is an organic moiety containing carbon (C) and hydrogen (H), or C, H, and nitrogen (N), or C, H and oxygen (O) and U is an integer >0.

4. The method of claim 1 wherein said second reactant is NH₃ or N₂H₄ and is injected at a flow rate of about 10 to 1000 sccm for a period of about 0.1 to 10 seconds.

5. The method of claim 1 wherein the third reactant is SiH₄ or B₂H₆ and is injected at a flow rate of about 10 to 1000 sccm for a period of about 0.1 to 10 seconds.

6. The method of claim 1 wherein said purging of the first, second, and third reactants is accomplished by applying a vacuum or by injecting Ar, He, or N₂ with a flow rate from about 10 to 1000 sccm for a period of about 0.1 to 10 seconds.

7. The method of claim 1 wherein recording and monitoring the number of monolayers deposited on said substrate is performed with the aid of a computer that is linked to the ALD process chamber.

8. The method of claim 1 wherein the process chamber pressure is less than 5 torr during the deposition of first, second, and third reactants.

9. The method of claim 1 wherein said thin film is deposited on a substrate having a pattern of openings formed in a stack of layers comprised of an upper dielectric layer on a lower etch stop layer and wherein said film is deposited on an exposed metal layer at the bottom of said opening to provide a conformal diffusion barrier layer.

10. The method of claim 9 further comprised of depositing a copper layer on said diffusion barrier layer and a performing a planarization process to thin the copper layer so that the Cu layer is coplanar with said dielectric layer.

11. An ALD method of forming a composite layer comprised of a plurality of monolayers on a substrate wherein said composite layer has the formula M_{1P}M_{2Q}O_{R} where M₁ is unequal to M₂, and wherein P, Q, and R are fractions between 0 and 1 and which together equal 1, comprising:
(a) loading a substrate in an ALD process chamber and bringing the process chamber to an acceptable pressure and temperature;
(b) performing a first cycle of steps a plurality of times and a second cycle of steps a plurality of times in any predetermined order in said process chamber to yield an acceptable thickness of said composite layer on said substrate and wherein said steps include:
(1) injecting a first reactant comprised of a metal (M₁) containing gas for a short interval and purging said first reactant;
(2) injecting a second reactant that is an oxygen source gas for a short interval and purging said second reactant;
(3) recording and monitoring the number of monolayers that have been deposited on the substrate; and
(4) injecting a third reactant comprised of a metal (M₂) containing gas for a short interval and purging said third reactant;
and wherein a first cycle of steps is defined as the flow sequence (1), (2), (3) which forms a first metal (M₁) oxide monolayer and wherein a second cycle of steps is defined as the flow sequence (4), (2), (3) which forms a second metal (M₂) oxide monolayer; and
(c) returning said process chamber to atmospheric pressure and unloading said substrate from said process chamber.

12. The method of claim 11 wherein bringing said ALD process chamber to an acceptable temperature and pressure comprises applying a vacuum to remove any resident gases and heating said ALD process chamber to a temperature between about 100° C. and 500° C.

13. The method of claim 11 wherein said first reactant is injected at a flow rate of about 10 to 1000 sccm for a period of about 0.1 to 10 seconds and has the formula M₁L_{T} or M₁R_{T} wherein M₁ is Hf and where L is a halogen (F, Cl, Br, I) and T is an integer >0, and where R is an alkyl group that may include N or O.

14. The method of claim 11 wherein said second reactant is H₂O or H₂O₂ and is injected at a flow rate of about 10 to 1000 sccm for a period of about 0.1 to 10 seconds.

15. The method of claim 11 wherein said third reactant is injected at a flow rate of about 10 to 1000 sccm for a period of about 0.1 to 10 seconds and has the formula M₂L_{T} or M₂R_{T} wherein M₂ is Zr, L is a halogen (F, Cl, Br, I), T is an integer >0, and where R is an alkyl group that may include N or 0.

16. The method of claim 11 wherein said purging of said first, second, or third reactants is accomplished by applying a vacuum or by injecting Ar, He, or N₂ with a flow rate from about 10 to 1000 sccm for a period of about 0.1 to 10 seconds.

17. The method of claim 11 wherein recording and monitoring the number of monolayers deposited on said substrate is performed with the aid of a computer that is linked to the ALD process chamber.

18. The method of claim 11 wherein the process chamber pressure is less than 5 torr during the deposition of first, second, and third reactants.

19. The method of claim 11 wherein said composite layer is deposited on a substrate comprised of shallow trench isolation features having an interfacial layer formed thereon, said film forms a gate dielectric layer in a partially formed NMOS or PMOS transistor.

20. An ALD method of forming a composite layer comprised of a plurality of monolayers on a substrate wherein said composite layer has the formula M₁ᵥSi_{X}B_{Y}N_{Z} in which M₁ is a metal and where V, X, Y, and Z are fractions between 0 and 1 and which together equal 1, comprising:
(a) loading a substrate in an ALD process chamber and bringing the process chamber to an acceptable pressure and temperature;
(b) performing a first cycle of steps a plurality of times and a second cycle of steps a plurality of times in a predetermined order to yield an acceptable thickness of said composite layer wherein said steps include:
(1) injecting a first reactant comprised of a metal (M₁) containing gas for a short interval and purging said first reactant;
(2) injecting a second reactant that is a nitrogen source gas for a short interval and purging said second reactant;
(3) injecting a third reactant that is a Si source gas for a short interval and purging said third reactant;
(4) recording and monitoring the number of monolayers that have been deposited on the substrate; and
(5) injecting a fourth reactant that is a B source gas for a short interval and purging said fourth reactant;
and wherein a first cycle of steps is defined as a first flow sequence (1), (2), (3), (4) that forms an M₁SiN monolayer, or a second flow sequence (1), (3), (4) which forms an M₁Si monolayer, or a third flow sequence (1), (2), (4) that forms an M₁N monolayer, and wherein a second cycle of steps is defined as a fourth flow sequence (1), (2), (5), (4) that forms an M₁BN monolayer, or a fifth flow sequence (1), (5), (4) that forms a M₁B monolayer, or said third flow sequence (1), (2), (4); and
(c) returning said process chamber to atmospheric pressure and unloading said substrate from said process chamber.

21. The method of claim 20 wherein bringing said ALD process chamber to an acceptable temperature and pressure comprises applying a vacuum to remove any resident gases and heating said ALD process chamber to a temperature between about 100° C. and 500° C.

22. The method of claim 20 wherein said first reactant is injected at a flow rate of about 10 to 1000 sccm for a period of about 0.1 to 10 seconds and has the formula M₁L_{T} or M₁E_{U} wherein M₁ is Ta, Ti, or W, and where L is a halogen (F, Cl, Br, I) and T is an integer >0, and where E is an organic moiety containing C and H, or C, H, and N, or C, H and O and U is an integer >0.

23. The method of claim 20 wherein said second reactant is NH₃ or N₂H₄ and is injected at a flow rate of about 10 to 1000 sccm for a period of about 0.1 to 10 seconds.

24. The method of claim 20 wherein said third reactant is SiH₄ or Si(OCH₃)₄ and is injected at a flow rate of about 10 to 1000 sccm for a period of about 0.1 to 10 seconds.

25. The method of claim 20 wherein said fourth reactant is B₂H₆ or BH₃ and is injected at a flow rate of about 10 to 1000 sccm for a period of about 0.1 to 10 seconds.

26. The method of claim 20 wherein said purging of said first, second, third and fourth reactants is accomplished by applying a vacuum or by injecting Ar, He, or N₂ with a flow rate from about 10 to 1000 sccm for a period of about 0.1 to 10 seconds.

27. The method of claim 20 wherein recording and monitoring the number of monolayers deposited on said substrate is performed with the aid of a computer that is linked to the ALD process chamber.

28. The method of claim 20 wherein the process chamber pressure is less than 5 torr during the injection of the first, second, third and fourth reactants.

29. The method of claim 20 wherein said composite layer is deposited on a substrate having a pattern of openings formed in a stack of layers comprised of an upper dielectric layer on a lower etch stop layer and wherein composite layer is deposited on an exposed metal layer at the bottom of said openings to provide a conformal diffusion barrier layer on said substrate.

30. The method of claim 29 further comprised of depositing a copper layer on said diffusion barrier layer and a performing a planarization process to thin the copper layer so that the Cu layer is coplanar with said dielectric layer.

31. An ALD method of forming a composite layer comprised of a plurality of monolayers on a substrate wherein said composite layer has the formula M₁ᵥM_{2w}SₓN_{Z} where V, W, X, and Z are fractions between 0 and 1 and that together equal 1 and wherein S is B or Si, and in which M₁ is a first metal and M₂ is a second metal that is unequal to M₁, comprising:
(a) loading a substrate in an ALD process chamber and bringing the process chamber to an acceptable pressure and temperature;
(b) performing a first cycle of steps a plurality of times and a second cycle of steps a plurality of times in a predetermined order to yield an acceptable thickness of said composite layer wherein said steps include:
(1) injecting a first reactant comprised of a metal (M₁) containing gas for a short interval and purging said first reactant;
(2) injecting a second reactant that is a nitrogen source gas for a short interval and purging said second reactant;
(3) injecting a third reactant that is a Si or B source gas for a short interval and purging said third reactant;
(4) recording and monitoring the number of monolayers that have been deposited on the substrate to complete a cycle; and
(5) injecting a fourth reactant comprised of a metal (M₂) containing gas for a short interval and purging said fourth reactant;
and wherein a first cycle of steps is defined as a first flow sequence (1), (2), (3), (4) that forms an M₁SiN or M₁BN monolayer, or a second flow sequence (1), (3), (4) which forms an M₁Si or M₁B monolayer, or a third flow sequence (1), (2), (4) that forms an M₁N monolayer, and wherein a second cycle of steps is defined as a fourth flow sequence (5), (2), (3), (4) that forms an M₂SiN or M₂BN monolayer, or a fifth flow sequence (5), (3), (4) that forms an M₂S₁ or M₂B monolayer, or a sixth flow sequence (5), (2), (4) that forms an M₂N monolayer; and
(c) returning said ALD process chamber to atmospheric pressure and unloading said substrate from said ALD process chamber.

32. The method of claim 31 wherein bringing said ALD process chamber to an acceptable temperature and pressure comprises applying a vacuum to remove any resident gases and heating said ALD process chamber to a temperature between about 100° C. and 500° C.

33. The method of claim 31 wherein said first reactant is injected at a flow rate of about 10 to 1000 sccm for a period of about 0.1 to 10 seconds and has the formula M₁L_{T} or M₁E_{U} wherein M₁ is Ta, Ti, or W, and where L is a halogen (F, Cl, Br, I) and T is an integer >0, and where E is an organic moiety containing C and H, or C, H, and N, or C, H and O and U is an integer >0.

34. The method of claim 33 wherein the first reactant is PDMAT, TaCl₄, WF₆, TiCl₄, TiF₄, or Ti{OCH(CH₃)₂}₄.

35. The method of claim 31 wherein said second reactant is NH₃ or N₂H₄ and is injected at a flow rate of about 10 to 1000 sccm for about 0.1 to 10 seconds.

36. The method of claim 31 wherein said third reactant is SiH₄, Si(OCH₃)₄, B₂H₆, or BH₃ and is injected at a flow rate of about 10 to 1000 sccm for about 0.1 to 10 seconds.

37. The method of claim 31 wherein said fourth reactant is injected at a flow rate of about 10 to 1000 sccm for a period of about 0.1 to 10 seconds and has the formula M₂L_{T} or M₂E_{U} wherein M₂ is Ta, Ti, or W and M₂ is unequal to M₁, and where L is a halogen (F, Cl, Br, I) and T is an integer >0, and where E is an organic moiety containing C and H, or C, H, and N, or C, H and O and U is an integer >0.

38. The method of claim 37 wherein the fourth reactant is PDMAT, TaCl₄, WF₆, TiCl₄, TiF₄, or Ti{OCH(CH₃)₂}₄.

39. The method of claim 31 wherein said purging of said first, second, third or fourth reactants is accomplished by applying a vacuum or by injecting Ar, He, or N₂ with a flow rate from about 10 to 1000 sccm for a period of about 0.1 to 10 seconds.

40. The method of claim 31 wherein recording and monitoring the number of monolayers deposited on said substrate is performed with the aid of a computer that is linked to the ALD process chamber.

41. The method of claim 31 wherein the ALD process chamber pressure is less than 5 torr during the injection of the first, second, third and fourth reactants.

42. The method of claim 31 wherein said composite layer is deposited on a substrate having a pattern of openings formed in a stack of layers comprised of an upper dielectric layer on a lower etch stop layer and wherein composite layer is deposited on an exposed metal layer at the bottom of said opening to provide a conformal diffusion barrier layer.

43. The method of claim 42 further comprised of depositing a copper layer on said diffusion barrier layer and a performing a planarization process to thin the copper layer so that the Cu layer is coplanar with said dielectric layer.

44. An ALD method of forming a composite layer comprised of a plurality of monolayers on a substrate wherein said composite layer has the formula M₁ᵥM_{2w}SiₓB_{Y}N_{Z} where V, W, X, Y, and Z are fractions between 0 and 1 and which together equal 1 and wherein M₁ is a first metal and M₂ is a second metal that is unequal to M₁, comprising:
(a) loading a substrate in an ALD process chamber and bringing the process chamber to an acceptable pressure and temperature;
(b) performing at least two cycles of steps a plurality of times and in a predetermined order to yield an acceptable thickness of said composite layer wherein said steps include:
(1) injecting a first reactant comprised of a metal (M₁) containing gas for a short interval and purging said first reactant;
(2) injecting a second reactant that is a nitrogen source gas for a short interval and purging said second reactant;
(3) injecting a third reactant that is a Si source gas for a short interval and purging said third reactant;
(4) recording and monitoring the number of monolayers that have been deposited on the substrate to complete a cycle;
(5) injecting a fourth reactant that is a B source gas for a short interval and purging said fourth reactant; and
(6) injecting a fifth reactant comprised of a metal (M₂) containing gas for a short interval and purging said fourth reactant; and
and wherein a first cycle of steps is defined as a first flow sequence (1), (2), (3), (4) that forms an M₁SiN monolayer, or a second flow sequence (1), (3), (4) which forms an M₁Si monolayer, or a third flow sequence (1), (2), (4) that forms an M₁N monolayer, and wherein a second cycle of steps is defined as a fourth flow sequence (6), (2), (3), (4) that forms an M₂SiN monolayer, or a fifth flow sequence (6), (3), (4) that forms an M₂Si monolayer, or a sixth flow sequence (6), (2), (4) that forms an M₂N monolayer, and wherein a third cycle of steps is defined as a seventh flow sequence (1), (2), (5), (4) that forms an M₁BN monolayer, or an eighth flow sequence (1), (5), (4) that forms an M₁B monolayer, or the third flow sequence; and wherein a fourth cycle of steps is defined as a ninth flow sequence (6), (2), (5), (4) that forms an M₂BN monolayer, or a tenth flow sequence (6), (5), (4) that forms an M₂B monolayer or the sixth flow sequence; and
(c) returning said ALD process chamber to atmospheric pressure and unloading said substrate from said ALD process chamber.

45. The method of claim 44 further comprised of performing a third cycle of steps a plurality of times in combination with said two cycles of steps in a predetermined order to produce said composite layer.

46. The method of claim 44 further comprised of performing a third cycle of steps and a fourth cycle of steps in combination with the at least two cycles of steps in a predetermined order so that all four cycles of steps are performed a plurality of times in forming said composite layer.

47. The method of claim 44 wherein bringing said ALD process chamber to an acceptable temperature and pressure comprises applying a vacuum to remove any resident gases and heating said ALD process chamber to a temperature between about 100° C. and 500° C.

48. The method of claim 44 wherein steps (1) and (6) comprise an injection of a reactant with a flow rate of about 10 to 1000 sccm for a period of about 0.1 to 10 seconds and wherein the first reactant has the formula M₁L_{T} or M₁E_{U} and the fifth reactant has the formula M₂L_{T} or M₂E_{U} wherein M₁ and M₂ are Ta, Ti, or W, and M₂ is unequal to M₁, and where L is a halogen (F, Cl, Br, I) and T is an integer >0, and where E is an organic moiety containing C and H, or C, H, and N, or C, H and O and U is an integer >0.

49. The method of claim 44 wherein the purging of said first, second, third, fourth, and fifth reactants is accomplished by applying a vacuum or by injecting Ar, He, or N₂ with a flow rate from about 10 to 1000 sccm for a period of about 0.1 to 10 seconds.

50. The method of claim 44 wherein steps (2), (3), and (5) comprise an injection of a reactant with a flow rate of about 10 to 1000 sccm for a period of about 0.1 to 10 seconds and wherein the second reactant is NH₃ or N₂H₄, the third reactant is SiH₄ or Si(OCH₃)₄, and the fourth reactant is B₂H₆ or BH₃.

51. The method of claim 44 wherein said composite layer is deposited on a substrate having a pattern of openings formed in a stack of layers comprised of an upper dielectric layer on a lower etch stop layer and wherein composite layer is deposited on an exposed metal layer at th bottom of said opening to provide a conformal diffusion barrier layer.

52. A composite layer having the formula M_{1V}S_{X}N_{Z} where V, X, and Z are fractions between 0 and 1 which together equal 1, said composite layer is comprised of a plurality of monolayers formed on a substrate, comprising:
(a) a first metal element M₁;
(b) a second element S which is Si or B; and
(c) a third element N that is nitrogen.

53. The composite layer of claim 52 wherein all monolayers have the formula M₁SN or M₁BN.

54. The composite layer of claim 52 comprised of a plurality of M₁SN monolayers and one or more M₁N and M₁S monolayers, said M₁N and M₁S monolayers are formed in any sequence with said M₁SN monolayers.

55. The composite layer of claim 52 comprised of a plurality of M₁BN monolayers and one or more M₁N and M₁B monolayers, said M₁N and M₁B monolayers are formed in any sequence with said M₁BN monolayers.

56. The composite layer of claim 52 wherein said first metal element is Ta, Ti, or W.

57. The composite layer of claim 52 wherein the thickness of said composite layer is between about 10 and 100 Angstroms.

58. The composite layer of claim 52 wherein said composite layer is formed on a substrate having a pattern of openings in a stack of layers comprised of an upper dielectric layer and a lower etch stop layer and wherein said composite layer is formed on an exposed metal layer at the bottom of said openings and is a conformal diffusion barrier metal layer.

59. A composite layer having the formula M_{1P}M_{2Q}O_{R} wherein P, Q, and R are fractions between 0 and 1 which together equal 1, said composite layer is comprised of a plurality of monolayers formed on a substrate, comprising
(a) a first metal element M₁;
(b) a second metal element M₂; and
(c) a third element O that is oxygen.

60. The composite layer of claim 59 wherein M₁ is Hf and M₂ is Zr and wherein said composite layer is comprised of ZrO₂ monolayers and HfO₂ monolayers and the ZrO₂ and HfO₂ monolayers are formed in any sequence.

61. The composite layer of claim 59 wherein the thickness of said composite layer is between about 10 and 100 Angstroms.

62. The composite layer of claim 59 wherein said composite layer is formed on an interfacial layer that is formed on a substrate having shallow trench isolation features formed therein, said composite layer is a gate dielectric layer in a MOSFET device.

63. A composite layer having the formula M_{1V}M_{2W}S_{X}N_{Z} where V, W, X, and Z are fractions between 0 and 1 which together equal 1, said composite layer is comprised of a plurality of monolayers formed on a substrate, comprising
(a) a first metal element M₁;
(b) a second metal element M₂;
(c) a third element N that is nitrogen; and
(d) a fourth element S which is Si or B.

64. The composite layer of claim 63 comprised of M₁SN and M₂SN monolayers or M₁BN and M₂BN monolayers which are formed in any sequence.

65. The composite layer of claim 63 comprised of M₁SN and M₂SN monolayers and one or more M₁N, M₁S, M₂N, and M₂S monolayers and wherein the aforementioned monolayers are formed in any sequence.

66. The composite layer of claim 63 comprised of M₁BN and M₂BN monolayers and one or more M₁N, M₁B, M₂N, and M₂B monolayers and wherein the aforementioned monolayers are formed in any sequence.

67. The composite layer of claim 63 wherein said first metal (M₁) element is Ta, Ti, or W and said second metal (M₂) element is Ta, Ti, or W and M₁ is unequal to M₂.

68. The composite layer of claim 63 wherein the thickness of said composite layer is between about 10 and 100 Angstroms.

69. The composite layer of claim 63 wherein said composite layer is formed on a substrate having a pattern of openings in a stack of layers comprised of an upper dielectric layer and a lower etch stop layer and wherein said composite layer is formed on an exposed metal layer at the bottom of said openings and is a conformal diffusion barrier metal layer.

70. A composite layer having the formula M_{1V}Si_{X}B_{Y}N_{Z} where V, X, Y, and Z are fractions between 0 and 1 which together equal 1, said composite layer is comprised of a plurality of monolayers formed on a substrate, comprising
(a) a first metal element M₁;
(b) a second element Si that is silicon;
(c) a third element N that is nitrogen; and
(d) a fourth element B which is boron.

71. The composite layer of claim 70 comprised of M₁SiN and M₁BN monolayers which are formed in any sequence.

72. The composite layer of claim 70 comprised of M₁SiN and M₁BN monolayers and one or more M₁N, M₁Si, and M₁B monolayers and wherein the aforementioned monolayers are formed in any sequence.

73. The composite layer of claim 70 wherein said first metal (M₁) element is Ta, Ti, or W.

74. The composite layer of claim 70 wherein the thickness of said composite layer is between about 10 and 1000 Angstroms.

75. The composite layer of claim 70 wherein said composite layer is formed on a substrate having a pattern of openings in a stack of layers comprised of an upper dielectric layer and a lower etch stop layer and is formed on an exposed metal layer at the bottom of said openings and is a conformal diffusion barrier metal layer.

76. A composite layer having the formula M_{1V}M_{2W}Si_{X}B_{Y}N_{Z} where V, W, X, Y, and Z are fractions between 0 and 1 which together equal 1, said composite layer is comprised of a plurality of monolayers formed on a substrate, comprising
(a) a first metal element M₁;
(b) a second metal element M₂;
(c) a third element N that is nitrogen;
(d) a fourth element Si which is silicon; and
(e) a fifth element B which is boron.

77. The composite layer of claim 76 comprised of M₁SiN and M₂BN monolayers which are formed in any sequence.

78. The composite layer of claim 76 comprised of M₁BN and M₂SiN monolayers which are formed in any sequence.

79. The composite layer of claim 76 comprised of three or more monolayers selected from the group of M₁SiN, M₂BN, M₁BN and M₂SiN monolayers.

80. The composite layer of claim 77 comprised of M₁SiN and M₂BN monolayers and one or more M₁N, M₁S₁, M₂N, and M₂B monolayers and wherein the aforementioned monolayers are formed in any sequence.

81. The composite layer of claim 78 comprised of M₁BN and M₂SiN monolayers and one or more M₁N, M₁B, M₂N, and M₂Si monolayers and wherein the aforementioned monolayers are formed in any sequence.

82. The composite layer of claim 79 comprised of M₁SiN, M₂BN, M₁BN and M₂SiN monolayers and one or more M₁N, M₂N, M₁B, M₂B, M₁ Si, and M₂Si monolayers and wherein the aforementioned monolayers are formed in any sequence.

83. The composite layer of claim 76 wherein said first metal (M₁) element is Ta, Ti, or W and said second metal (M₂) element is Ta, Ti, or W, and M₁ is unequal to M₂.

84. The composite layer of claim 76 wherein the thickness of said composite layer is between about 10 and 100 Angstroms.

85. The composite layer of claim 76 wherein said composite layer forms a diffusion barrier layer in a copper interconnect structure.
